(19) United States
(12) Patent Application Publication
(10) Pub. No.: US 2017/0178994 A1
(43) Pub. Date: Jun. 22, 2017

(54) INTEGRATED CIRCUIT PACKAGE SUPPORT STRUCTURES

(71) Applicant: Intel Corporation, Santa Clara, CA (US)

(72) Inventors: Michael Hui, Tacoma, WA (US); Rashelle Yee, Puyallup, WA (US); Jonathan Thibado, Beaverton, OR (US); Daniel P. Carter, Olympia, WA (US); Shelby Ferguson, Lacey, WA (US); Anthony P. Valpiani, Olympia, WA (US); Russell S. Aoki, Tacoma, WA (US); Jonathon Robert Carstens, Lacey, WA (US); Joseph J. Jasniewski, Olympia, WA (US); Harvey R. Kofstad, Vernonia, OR (US); Michael Brazel, Fedeal Way, WA (US); Tracy Clack, Spanaway, WA (US); Viktor Vogman, Olympia, WA (US); Penny Woodcock, Beaverton, OR (US); Kevin J. Ceurter, Olympia, WA (US); Hongfei Yan, Mesa, AZ (US)

(73) Assignee: Intel Corporation, Santa Clara, CA (US)

(21) Appl. No.: 14/975,943

(22) Filed: Dec. 21, 2015

(51) Int. Cl. H01L 23/34; H01L 21/48; H01L 23/498

(52) U.S. Cl. CPC H01L 23/345; H01L 23/49816; H01L 23/49827; H01L 23/49833; H01L 23/49838; H01L 21/4871; H01L 21/4853

(57) ABSTRACT

Disclosed herein are integrated circuit (IC) package support structures, and related systems, devices, and methods. In some embodiments, an IC package support structure may include a first heater trace, and a second heater trace, wherein the second heater trace is not conductively coupled to the first heater trace in the IC package support structure.

### TECHNICAL FIELD

The present disclosure relates generally to integrated circuits (ICs), and more particularly, to IC package support structures.

### BACKGROUND

Integrated circuit (IC) packages often include computing components (e.g., processing devices) that generate significant heat during operation. This heat is typically managed by heat sinks and other heat dissipation devices, and by restricting the performance of the computing component to stay within a temperature range of reliable operation.

### BRIEF DESCRIPTION OF THE DRAWINGS

Embodiments will be readily understood by the following detailed description in conjunction with the accompanying drawings. Embodiments are illustrated by way of example, and not by way of limitation, in the figures of the accompanying drawings.

FIG. 1 is a side cross-sectional view of an integrated circuit (IC) package assembly including an IC package disposed on an IC package support structure, in accordance with various embodiments.

FIG. 2 is a side cross-sectional view of an embodiment of the IC package assembly of FIG. 1 in which the IC package support structure is an interposer, in accordance with various embodiments.

FIG. 3 is a side cross-sectional view of an embodiment of the IC package assembly of FIG. 1 in which the IC package support structure is a printed circuit board (PCB), in accordance with various embodiments.

FIG. 4 is a side cross-sectional view of an assembly subsequent to bringing a heater control device and an IC package in proximity to the IC package support structure of FIG. 1, in accordance with various embodiments.

FIG. 5 is a side cross-sectional view of an assembly subsequent to using the heater control device of FIG. 4 to couple the IC package to the IC package support structure, in accordance with various embodiments.

FIG. 6 is a top view of a stack of heater traces disposed in multiple layers of an IC package support structure, in accordance with various embodiments.

FIGS. 7A-7E illustrate an arrangement of layers in an IC package support structure that may provide the heater trace stack of FIG. 6, in accordance with various embodiments.

FIG. 8 is a top view of a stack of heater traces disposed in multiple layers of an IC package support structure, in accordance with various embodiments.

FIG. 9 illustrates a layer of an IC package support structure that, in conjunction with the layers of FIGS. 7A, 7B, 7C, and 7E, may provide the heater trace stack of FIG. 8, in accordance with various embodiments.

FIGS. 10A-10H illustrate an example stack of layers in an IC package support structure, in accordance with various embodiments.

FIG. 11 illustrates a heater trace having portions with different widths in an IC package support structure, in accordance with various embodiments.

FIG. 12 is a block diagram of a reflow control system, in accordance with various embodiments.

FIG. 13 is a flow diagram of a method of manufacturing an IC package support structure, in accordance with various embodiments.

FIG. 14 is a flow diagram of a method of attaching IC packages to an IC package support structure, in accordance with various embodiments.

FIG. 15 is a block diagram of an example computing device that may include an IC package support structure in accordance with the teachings of the present disclosure.

### DETAILED DESCRIPTION

Disclosed herein are integrated circuit (IC) package support structures, and related systems, devices, and methods. In some embodiments, an IC package support structure may include a first heater trace and a second heater trace, wherein the second heater trace is not conductively coupled to the first heater trace in the IC package support structure.

Some IC package assemblies may include an IC package support structure with heaters designed to cause local reflow of the solder attaching an IC package to the support structure (e.g., to facilitate the removal and reattachment of the IC package without the need for sockets or factory machinery). In such assemblies, thermal mismatch between materials used in the IC package assembly may result in deformation of various components in the IC package assembly as the heaters cause solder reflow, and this deformation may lead to mechanical failure in the IC package assembly and/or failure of the reflow process.

Various ones of the embodiments disclosed herein include design features to facilitate the formation of a desired temperature profile within an IC package support structure, while limiting the likelihood of mechanical failure and achieving successful reflow. IC package support structures including one or more of these design features may exhibit advantageous thermal properties (e.g., a uniform temperature profile) and may be readily manufactured. In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale.

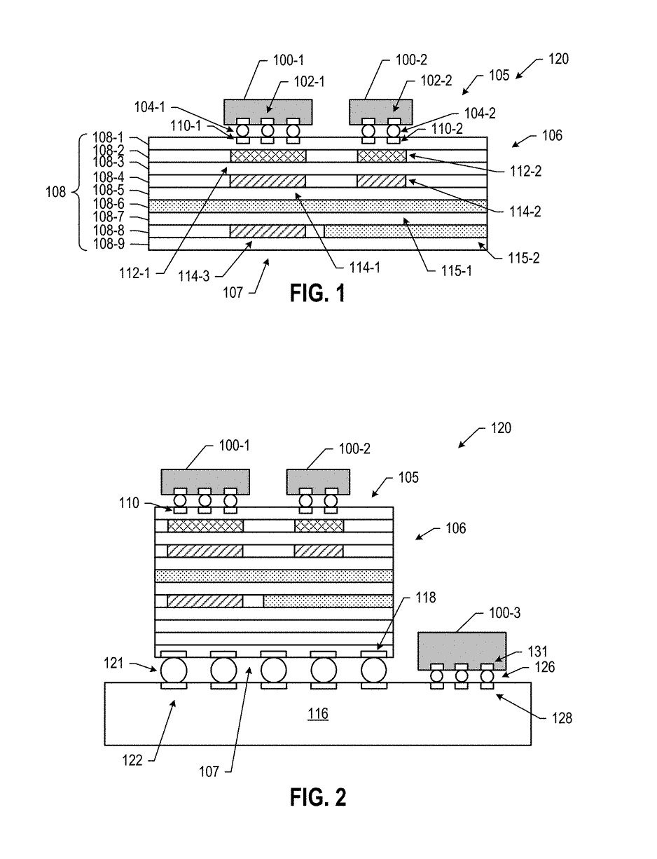

FIG. 1 is a side cross-sectional view of an IC package assembly 120 including IC packages 100-1 and 100-2 disposed on an IC package support structure 106, in accordance with various embodiments. The IC package support structure 106 may include one or more heater traces 114. As discussed in detail below, the heater traces 114 of the IC package support structure 106 may be used to facilitate a local reflow temperature for the attachment/detachment of the IC packages 100. In some embodiments, the IC package assembly 120 may include one or more heat spreaders, thermal interface material (TIM), or other thermal management components, such as a heat sink or a liquid cooling system (not shown). These thermal management components may be coupled to the IC package 100 or the IC package support structure 106, for example.

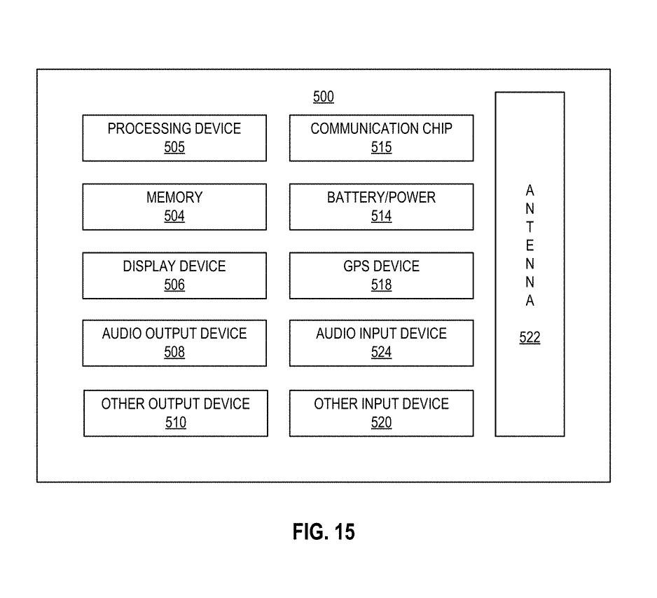

The IC packages 100-1 and 100-2 may be ball grid array (BGA) packages and may include conductive contacts 102-1 and 102-2, respectively, that are coupled to conductive contacts 110-1 and 110-2 of the IC package support structure 106 via solder 104-1 and 104-2, respectively. Each IC package 100 may include one or more IC dies (not shown) in electrical communication with the IC package support structure 106 via the conductive contacts 102. The IC dies may have their own conductive contacts coupled to the conductive contacts 102 (e.g., via flip chip or wire bonding to an IC package substrate). An IC die included in an IC package 100 may include any suitable computing component, such as a central processing unit (CPU), graphics processing unit (GPU), any other processing device, a memory device, passive components, or any combination of computing components. For example, the IC package 100 may include any suitable ones of the components discussed below with reference to the computing device 500 of FIG. 15. In some embodiments, the IC packages 100 may include an underfill material, an overmold material, or may otherwise take the form of any IC packages known in the art.

The IC package support structure 106 may include one or more heater traces 114. The heater traces 114 of the IC package support structure 106 may be proximate to vias (not shown) coupled to the conductive contacts 110, and may be arranged such that, when power is selectively dissipated in one or more of the heater traces 114, the heater traces 114 generate heat conducted by the vias to the conductive contacts 110 to cause the solder 104-1 or 104-2 disposed on the conductive contacts 110-1 or 110-2 to melt, enabling the attachment and/or detachment of the IC packages 100-1 or 100-2, respectively. Different ones of the heater traces 114 (e.g., the heater traces 114-1, 114-2, and 114-3) may be provided with power to melt solder 104 disposed on different groupings of the conductive contacts 110; for example, the heater traces 114 may generate heat to melt the solder 104-1 disposed on the conductive contacts 110-1, but not the solder 104-2 disposed on the conductive contacts 110-2, or vice versa.

The heat generated by the heater traces 114 may particularly heat vias (not shown for clarity of illustration, but discussed below) in the IC package support structure 106 that couple to the conductive contacts 110, thereby heating the conductive contacts 110. In FIG. 1, the IC package support structure 106 includes heater traces 114-1, 114-2, and 114-3, but the specific number of heater traces 114 shown in FIG. 1 is simply illustrative, and more or fewer heater traces 114 may be included in the IC package support structure 106. Additionally, the specific arrangement of heater traces 114 shown in FIG. 1 is simply illustrative, and any suitable arrangement may be used. The amount of power provided to the heater traces 114 to melt the solder 104 on a particular set of conductive contacts 110 may depend on the particular temperature to be achieved to melt the solder 104 (which may depend on the solder material), the arrangement of the heater traces 114, and thermal constraints on other portions of the IC package support structure 106 (e.g., other conductive contacts 110 having solder 104 that is not to be melted), for example.

In some embodiments, the IC package support structure 106 may include one or more temperature sensor traces 112. In FIG. 1, for example, the IC package support structure 106 includes temperature sensor traces 112-1 and 112-2. Each temperature sensor trace 112 may be formed of an electrically conductive material (e.g., a metal, such as copper) whose electrical resistance changes as a function of the equivalent temperature of the temperature sensor trace 112. As used herein, the “equivalent temperature” may represent a weighted average of the temperature of a temperature sensor trace 113; for example, if 90% of the length of a constant width temperature sensor trace 113 is 10° and the remaining 10% of the length of the temperature sensor trace 113 is 20°, the equivalent temperature for the temperature sensor trace 113 may be 11°. The function relating electrical resistance and equivalent temperature may be given by:

R=Rref(1−α(T−Tref))

where R is the electrical resistance of the temperature sensor trace 112 at the equivalent temperature T, Rref is a reference electrical resistance of the temperature sensor trace 112 at a reference temperature Tref, and a is the temperature coefficient of resistance for the material forming the temperature sensor trace 112. The values of a, Rref, and Tref may be experimentally determined or may be known in the art, and are accordingly not discussed further herein. When a, Rref, and Tref are known for a particular temperature sensor trace 112, a measurement of the electrical resistance R of the temperature sensor trace 112 may enable the equivalent temperature T of the temperature sensor trace 112 to be determined in accordance with the above function. The values of a, Rref, and Tref may be stored in a memory device (e.g., in a lookup table) and may be accessed as desired. In some embodiments, functions other than the function given above may more accurately describe the relationship between electrical resistance R and equivalent temperature T of a temperature sensor trace 112 (e.g., as determined experimentally); in such embodiments, the parameters of the more accurate function may be stored in a memory device (e.g., in a lookup table) and used to determine the equivalent temperature T based on the electrical resistance R. In some embodiments, Tref and Rref measurements may be taken during an initialization phase of the control hardware monitoring the temperature sensor trace 112.

In some embodiments, the temperature data provided by the resistance of the temperature sensor traces 112 may be used by a heater control device 130 (discussed below with reference to FIGS. 4-5 and 12) when providing power to the heater traces 114 in order to achieve particular temperatures at one or more locations in the IC package support structure 106. For example, the temperature sensor traces 112 of the IC package support structure 106 may be used to measure the equivalent temperature near the conductive contacts 110, and that temperature may be provided to a feedback loop in the heater control device 130 to control the amount of power provided to the heater traces 114 to achieve a desired solder-melting temperature at the conductive contacts 110. The “amount” of power may be quantified by the duty cycle settings of a pulse width modulated (PWM) current or voltage signal, the AC root-mean-square (RMS) or DC value of a current or voltage signal, or a combination thereof, for example.

The feedback loop may also be used to ensure that other portions of the IC package support structure 106 do not exceed a maximum temperature and/or the temperature across the IC package support structure 106 is relatively uniform to mitigate any mechanical failures that may occur as a result of thermal expansion mismatches. The specific number of temperature sensor traces 112 shown in FIG. 1 is simply illustrative, and more or fewer temperature sensor traces 112 may be included in the IC package support structure 106. Additionally, the specific arrangement of temperature sensor traces 112 shown in FIG. 1 is simply illustrative, and any suitable arrangement may be used. In some embodiments, no temperature sensor traces 112 may be included in the IC package support structure 106.

The IC package support structure 106 may include multiple layers 108 (in particular, layers 108-1 through 108-9). One or more of these layers 108 may include one or more heater traces 114 and/or temperature sensor traces 112. For example, in the embodiment illustrated in FIG. 1, the layer 108-2 includes two temperature sensor traces 112-1 and 112-2, the layer 108-4 includes two heater traces 114-1 and 114-2, and the layer 108-8 includes a heater trace 114-3. Different layers including heater traces 114 and/or temperature sensor traces 112 may be spaced apart by insulator layers (e.g., the layers 108-3, 108-5, and 108-7 of FIG. 1). Some of the layers 108 may be metal layers that include signal routing traces, and some of the layers 108 may be insulator layers (e.g., formed of a dielectric material) that include vias to electrically couple different metal layers, as known in the art. For example, the layer 108-1 may be an insulator layer that includes vias (not shown) to route signals to/from the conductive contacts 110. Signal routing traces and vias are not shown in FIG. 1 for ease of illustration, and may be formed in accordance with any technique known in the art. In some embodiments, the IC package support structure 106 may include multiple metal layers separated from one another by layers of dielectric material and interconnected by electrically conductive vias. Any one or more of the metal layers may be formed in a desired circuit pattern of signal routing traces to route electrical signals (optionally in conjunction with other metal layers) between the components of the IC package support structure 106. In some embodiments, a layer 108 of the IC package support structure 106 may include both signal routing traces and one or more heater traces 114 and/or temperature sensor traces 112. For example, the layers 108-2, 108-4, and/or 108-8 may include signal routing traces. In other embodiments, signal routing traces, heater traces 114, and/or temperature sensor traces 112 may be segregated in different layers 108.

In some embodiments, the IC package support structure 106 may include one or more metal planes 115. For example, FIG. 1 illustrates a metal plane 115-1 that spans all of the layer 108-6, and a metal plane 115-2 that “shares” the layer 108-8 with the heater trace 114-3. The metal planes 115 included in the IC package support structure 106 may act as heat spreaders and may help to achieve a uniform temperature profile across the IC package support structure 106. As noted above, a uniform temperature profile may reduce the likelihood of cracking, delamination, or other mechanical failures that may arise as a result of mismatches in the coefficient of thermal expansion between different materials included in the IC package assembly 120. The metal planes 115 included in the IC package support structure 106 may include holes (not shown) through which vias may extend (and from which the vias may be electrically insulated) as part of the signaling network in the IC package support structure 106. The metal planes 115 may be distinguished from metal planes that are sometimes included in conventional substrates for providing power or ground references; the metal planes 115 may not be conductively coupled to power or ground contacts of the IC package support structure 106.

When a metal plane 115 shares a layer 108 with a heater trace 114, the thickness of the metal plane 115 may be constrained to be the same as the thickness of the heater trace 114. As the thickness of a heater trace 114 increases, the resistance of the heater trace 114 decreases, and thus more current is required for the heater trace 114 to generate a desired amount of heat. Thus, in embodiments in which a metal plane 115 is desired with a thickness greater than a tolerable thickness for a heater trace 114 with which the metal plane 115 shares a layer 108, the metal plane 115 may be implemented by two or more metal planes 115 in adjacent layers 108.

The IC package support structure 106 may be formed of an epoxy resin, a fiberglass-reinforced epoxy resin, a ceramic material, or a polymer material such as polyimide. In some implementations, the IC package support structure 106 may be formed of alternate rigid or flexible materials, such as silicon, germanium, and other group III-V and group IV materials. The IC package support structure 106 may include metal interconnects and vias (not shown), including but not limited to through-silicon vias (TSVs). The IC package support structure 106 may further include embedded devices (not shown), including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical system (MEMS) devices may also be formed on the IC package support structure 106.

In some embodiments, the heater traces 114 and/or the temperature sensor traces 112 in the IC package support structure 106 may have connection terminals (not shown) exposed at a surface of the IC package support structure 106 at which a heater control device 130 (discussed below with reference to FIGS. 4-5 and 12) may make electrical contact with the heater traces 114 (to provide power to the heater traces 114 to cause the heater traces 114 to generate heat) and/or with the temperature sensor traces 112 (to measure their electrical resistance and determine their equivalent temperatures).

In some embodiments, the IC package support structure 106 may take the form of an interposer. For example, FIG. 2 is a side cross-sectional view of an embodiment of the IC package assembly 120 of FIG. 1 in which the IC package support structure 106 is an interposer, in accordance with various embodiments. The IC package support structure 106 may include conductive contacts 118 disposed at a first face 107 of the IC package support structure 106, and the conductive contacts 110 may be disposed at a second face 105 of the IC package support structure. The conductive contacts 118 may be coupled to conductive contacts 122 of a PCB 116 via solder 121, and the conductive contacts 110 may be coupled to the IC packages 100, as discussed below with reference to FIG. 5. Additional IC packages, such as the IC package 100-3 of FIG. 2, may be coupled to the PCB 116. The IC package 100-3 may take the form of any of the IC packages 100 disclosed herein and may include conductive contacts 131 coupled to conductive contacts 128 of the PCB 116 via solder 126. In some embodiments, the PCB 116 may be a motherboard or other suitable substrate. The IC package support structure 106 of FIG. 2 may include electrical signal routing traces and vias arranged to route electrical signals between the conductive contacts 110 and the conductive contacts 122 via the conductive contacts 118. The components of the IC package support structure 106 of FIG. 2 may take the form of any of the embodiments of the IC package support structure 106 discussed above with reference to FIG. 1.

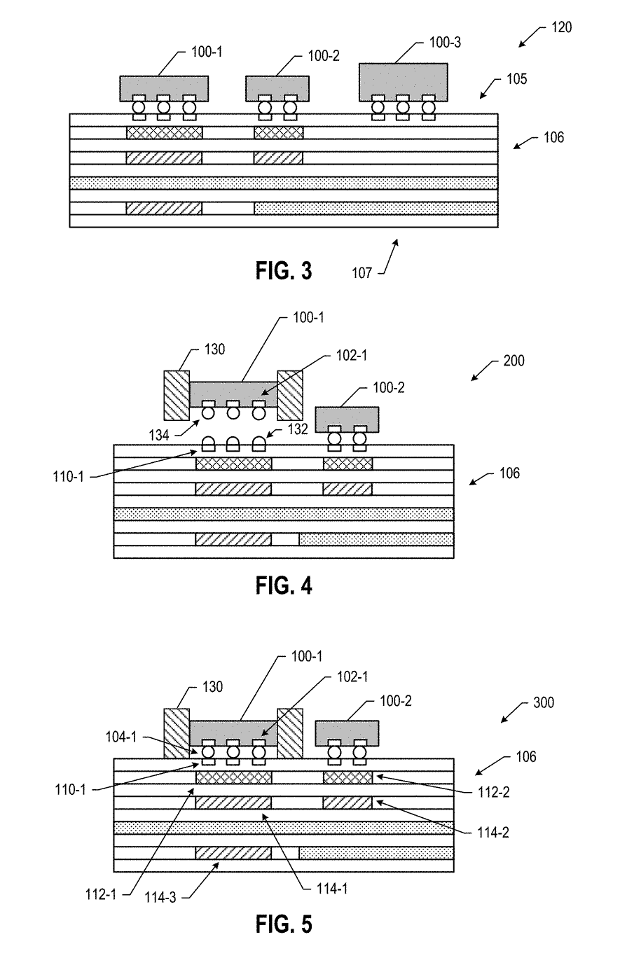

In some embodiments, the IC package support structure 106 may take the form of a PCB (e.g., a motherboard). FIG. 3 is a side cross-sectional view of an embodiment of the IC package assembly 120 of FIG. 1 in which the IC package support structure 106 is a PCB having the IC packages 100-1, 100-2, and 100-3 disposed thereon, in accordance with various embodiments. The components of the IC package support structure 106 of FIG. 3 may take the form of any of the embodiments of the IC package support structure 106 discussed above with reference to FIG. 1.

As noted above, the heater traces 114 included in the IC package support structure 106 may be used to facilitate the attachment and detachment of one or more of the IC packages 100 from the IC package support structure 106. FIG. 4 is a side cross-sectional view of an assembly 200 subsequent to bringing a heater control device 130 and an IC package 100-1 in proximity to the IC package support structure 106 of FIG. 1, in accordance with various embodiments. In some embodiments, the heater control device 130 may include a mechanical clamp or other structure to hold the IC package 100-1, and may also include alignment features (e.g., alignment corners, pins) to facilitate the alignment of the heater control device 130 (while holding the IC package 100-1) into a desired position on the IC package support structure 106. Solder balls 134 may be disposed on the conductive contacts 102-1 of the IC package 100-1, and solder paste 132 may be disposed on the conductive contacts 110-1. Proper alignment of the heater control device 130 (and IC package 100-1) with the IC package support structure 106 may align the conductive contacts 102-1 with corresponding conductive contacts 110-1, may align heater trace contacts (not shown) of the heater control device 130 with connection terminals (not shown) of the heater traces 114, and may align temperature sensor trace contacts (not shown) of the heater control device 130 with connection terminals (not shown) of the temperature sensor traces 112.

FIG. 5 is a side cross-sectional view of an assembly 300 subsequent to using the heater control device 130 of FIG. 4 to couple the IC package 100-1 to the IC package support structure 106, in accordance with various embodiments. In particular, once the heater control device 130 and the IC package 100-1 are properly aligned with the IC package support structure 106, the heater control device 130 may cause power to be dissipated in the heater traces 114 of the IC package support structure 106 to melt the solder balls 134 and the solder paste 132 to conductively couple the conductive contacts 102-1 of the IC package 100-1 to the conductive contacts 110-1 of the IC package support structure 106. As discussed above, in some embodiments, the heater control device 130 may use temperature feedback from the temperature sensor traces 112 to adjust the amount of power provided to the heater traces 114 to achieve a desired temperature profile in the IC package support structure 106. Once the solder balls 134 and the solder paste 132 have achieved desired reflow conditions, the heater control device 130 may allow the heater traces 114 to cool, thereby allowing the newly formed solder connections 104 between the conductive contacts 102-1 and the conductive contacts 110-1 to solidify. The heater control device 130 may then disengage from the IC package 100-1 and the IC package support structure 106.

If the IC package 100-1 is to be detached from the IC package support structure 106, an analogous procedure may be performed: the heater control device 130 may be brought into alignment with the IC package 100-1 and the IC package support structure 106, power may be selectively provided to the heater traces 114 to cause the solder 104-1 to melt, and the IC package 100-1 may be removed.

In some embodiments, the heater control device 130 may be temporarily coupled to the IC package 100-1, and may be disengaged from the IC package 100-1 when attachment/detachment of the IC package 100-1 is not under way. For example, the heater control device 130 may be a reusable, modular device that can be used in the field or in a factory setting. Such a heater control device 130 may be designed for use with one particular IC package design or may be usable with multiple different IC package designs. In other embodiments, the heater control device 130 may be permanently coupled to the IC package 100-1. In some embodiments, the heater control device 130 may be temporarily coupled to the IC package support structure 106 and may be disengaged from the IC package support structure 106 when attachment/detachment of the IC package 100-1 is not under way. In other embodiments, the heater control device 130 may be permanently coupled to the IC package support structure 106.

In some embodiments, the heater control device 130 may include its own power source to drive the heater traces 114, while in other embodiments, the heater control device 130 may utilize a power source included in the IC package support structure 106 or the PCB 116.

By facilitating the attachment/detachment of the IC package 100-1, the IC package support structure 106 may improve on conventional attachment methodologies. Such conventional attachment methodologies include conventional BGA attachment, in which an IC package is soldered to a component. Conventional BGA attachment typically exhibits high reliability and good high-speed signaling performance, but must be reworked in a controlled factory setting with specialized equipment and training, and therefore BGA packages are not readily attached and detached during testing or in the field. Another example of a conventional attachment methodology is a land grid array (LGA), in which an IC package is fitted into a socket. IC packages with LGA connections are readily attached and detached, but LGA sockets are prone to damage (and are themselves not readily replaced), and may exhibit poor high-speed signal performance (e.g., by adding impedance and cross talk to the signal chain). Another example of a conventional attachment methodology is metal particle interconnect (MPI), another socket methodology. Conventional MPI sockets are too expensive to be suited for high-volume production, and may add impedance to the signal chain.

The IC package support structure 106 may provide the advantages of conventional BGA attachment by facilitating a direct solder connection between the IC package support structure 106 and the IC package 100-1, while facilitating easy attachment/detachment by the use of the heater traces 114 (achieving or surpassing the ease of sockets). When the heater control device 130 is a modular component, a technician in the factory or field can readily install or replace the IC package 100-1.

The layout and arrangement of heater traces 114 among one or more layers 108 of an IC package support structure 106 will affect the temperature profile of the IC package support structure 106 when power is provided to the heater traces 114. In some embodiments, it may be desirable to controllably produce a uniform temperature profile across the conductive contacts 110 coupled to an IC package 100, and/or across the IC package support structure 106, and/or across the IC package assembly 120. Temperature uniformity across the conductive contacts 110 may ensure consistent and effective reflow of the solder 104 when the IC package 100 is being attached/detached. Using the heater traces 114 to achieve temperature uniformity within the IC package support structure 106 may mitigate the nonuniform thermal losses experienced by different portions of the IC package support structure 106 (with large heat losses experienced by power/ground signal planes, lesser heat losses experienced by signal routing traces, and even lesser heat losses experienced by test pins and unused features). Temperature uniformity within the IC package assembly 120 may minimize the likelihood of a mechanical failure due to warpage caused by thermal mismatch of different components in the IC package assembly 120.

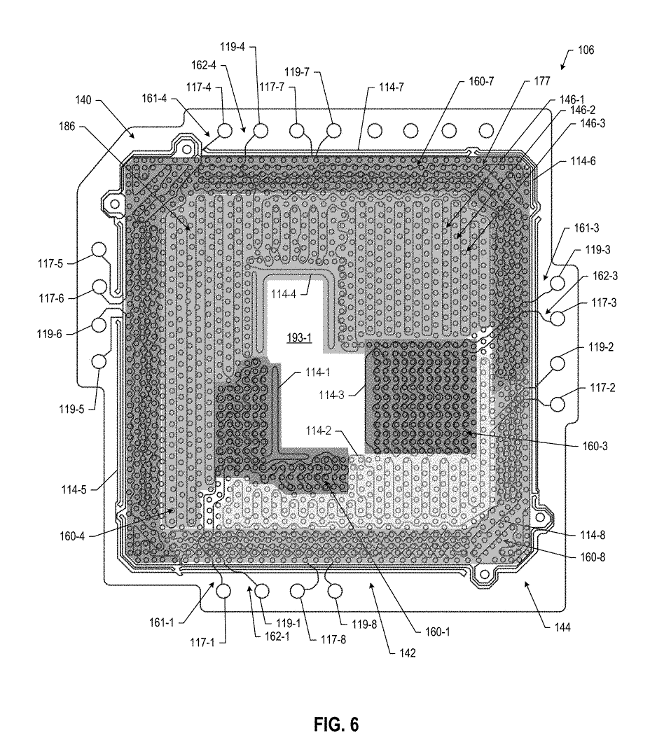

Disclosed herein are a number of heater trace design features that may be included in various embodiments of the IC package support structure 106 to achieve various thermal management objectives. The heater trace design features include features related to the number of heater traces 114 and their arrangement within a layer 108, the geometry of the layout of a particular heater trace 114, and the arrangement of heater traces 114 within different layers 108, among others. These heater trace design features are illustrated below with reference to the examples of FIGS. 6-11. It will be noted that the examples of FIGS. 6-11 include a number of design features that may not be explicitly discussed in the body of this specification for ease of illustration, but one of ordinary skill in the art will recognize the presence of these design features.

Although heater traces 114 are discussed below with reference to FIGS. 6-11, any of the heater traces 114 disclosed herein may be used as temperature sensor traces 112 (e.g., by measuring the resistance of the heater trace 114, as discussed above). In particular, any individual heater trace 114 may be used alternately as both a heater trace and the temperature sensor trace (e.g., by alternately providing power to the trace and measuring the resistance of the trace). Thus, any of the heater trace designs disclosed herein may also be used as temperature sensor trace designs.

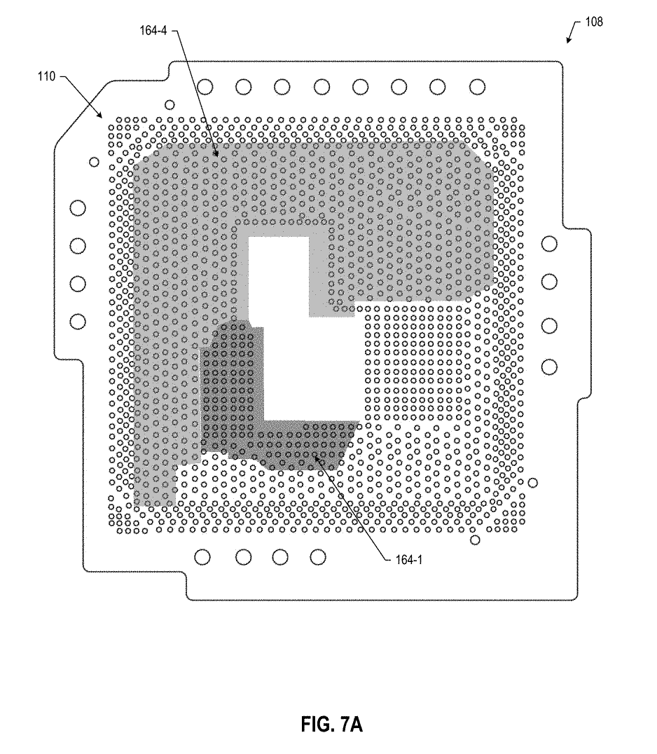

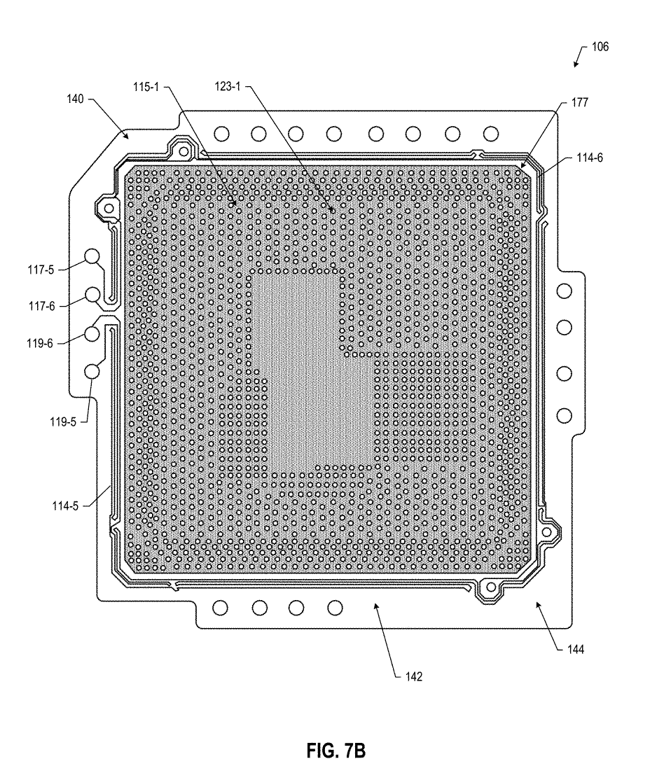

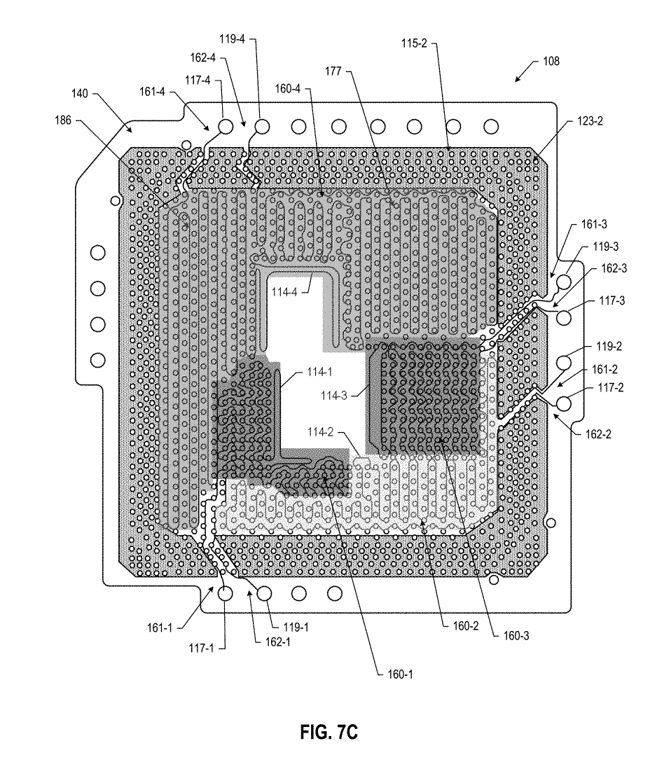

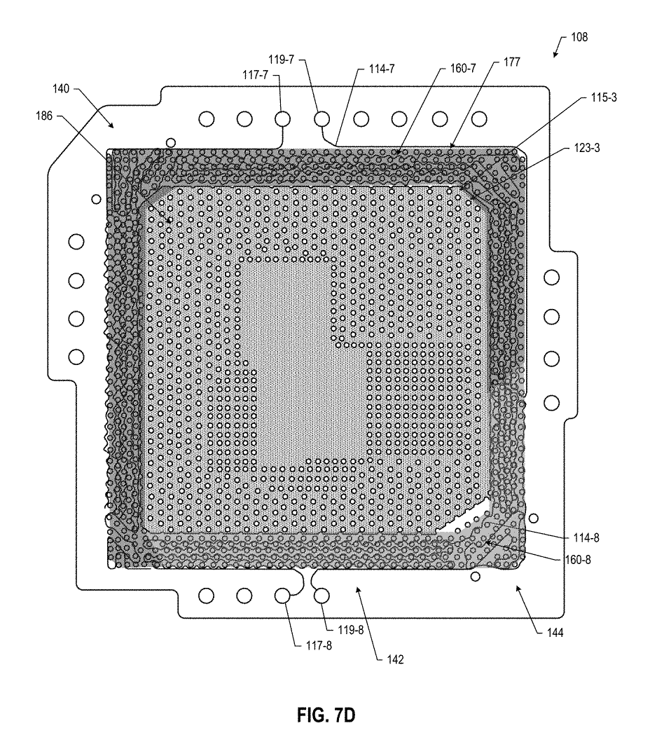

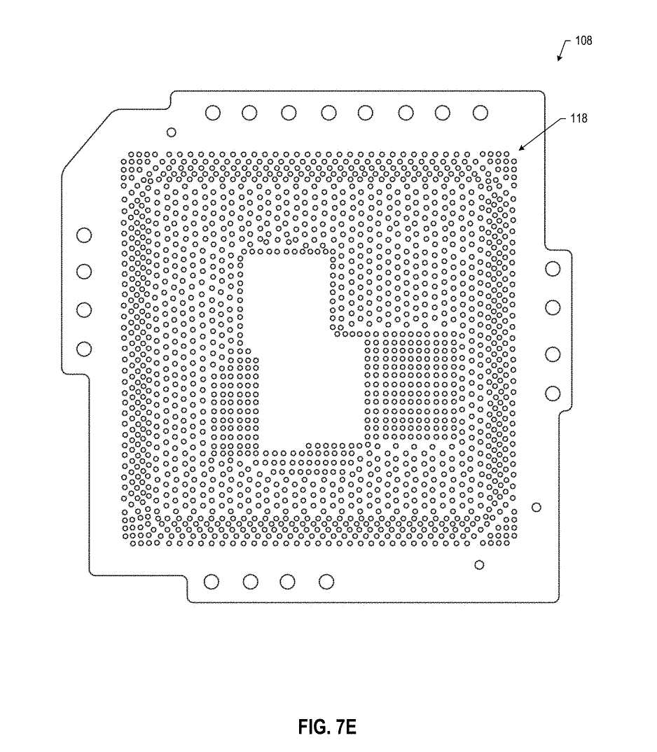

FIG. 6 is a top view of a stack of heater traces 114 disposed in multiple layers 108 of the IC package support structure 106, and FIGS. 7A-7E illustrate one particular arrangement of layers 108 in an IC package support structure 106 that may provide the heater trace stack of FIG. 6. In particular, the embodiment of FIG. 6 includes heater traces 114-1, 114-2, 114-3, 114-4, 114-5, 114-6, 114-7, and 114-8. None of the heater traces 114 illustrated in FIG. 6 are conductively coupled to each other in the IC package support structure 106, and each of the heater traces 114 has a first connection terminal 117 and a second connection terminal 119. In the embodiment of FIG. 6, all of the connection terminals 117 and 119 are disposed in a perimeter region 140 of the IC package support structure 106. The central region 186 of the IC package support structure 106 may include vias 177, which may be coupled to corresponding ones of the conductive contacts 110. As discussed above with reference to FIGS. 1-5, the conductive contacts 110 may be used to couple the IC package support structure 106 to one or more IC packages 100 (e.g., BGA IC packages 100). In the IC package support structure 106 of FIG. 6 (and the other IC package support structures disclosed herein), heat generated by different ones of the heater traces 114 may be absorbed by proximate ones of the vias 177 and conducted to corresponding ones of the conductive contacts 110 to cause reflow of the solder 104, as discussed above.

In some embodiments of the IC package support structures 106 disclosed herein, some of the heater traces 114 may be disposed in the perimeter of the IC package support structure 106, while other heater traces 114 may be disposed in a central region of the IC package support structure 106. For example, in FIG. 6, the heater traces 114-5 and 114-6 are also disposed in the perimeter region 140, while the heater traces 114-1, 114-2, 114-3, and 114-4 are disposed in a central region 186. In particular, the heater trace 114-6 wraps around the central region 186, and most of the length of the heater trace 114-6 is disposed at the corners 144 of the IC package support structure 106 (with some of the length of the heater trace 114-6 disposed along the edges 142 of the IC package support structure 106). The heater trace 114-5 also wraps around the central region 186, and most of the length of the heater trace 114-5 is disposed along the edges 142 of the IC package support structure 106 (with some of the length of the heater trace 114-5 disposed at the corners 144 of the IC package support structure 106). In the embodiment illustrated in FIG. 6, neither the heater trace 114-5 nor the heater trace 114-6 extend into the central region 186.

Different ones of the heater traces 114 included in an IC package support structure 106 may have different footprints. For example, in FIG. 6, the heater trace 114-1 has a footprint 160-1 shaped substantially as an “L,” with a first connection terminal extension 161-1 and a second connection terminal extension 162-1 extending from the footprint 160-1 to the connection terminals 117-1 and 119-1, respectively. The heater trace 114-3 has a convex footprint 160-3 (in particular, a rectangular footprint) with a first connection terminal extension 161-3 and a second connection terminal extension 162-3 extending from the footprint 160-3 to the connection terminals 117-3 and 119-3, respectively. The heater trace 114-4 has a footprint 160-4 with a first connection terminal extension 161-4 and a second connection terminal extension 162-4 extending from the footprint 160-4 to the connection terminals 117-4 and 119-4, respectively. The heater traces 114-5 and 114-6 do not have their footprints labeled in FIG. 6, but as discussed above, each extends around the perimeter region 140 of the IC package support structure 106. The heater trace 114-7 has a footprint 160-7 shaped substantially as a “U,” with a first connection terminal extension 161-7 and a second connection terminal extension 162-7 extending from the footprint 160-7 to the connection terminals 117-7 and 119-7, respectively. The heater trace 114-8 has footprint 160-8 shaped substantially as an “L,” with a first connection terminal extension 161-8 and a second connection terminal extension 162-8 extending from the footprint 160-8 to the connection terminals 117-8 and 119-8, respectively.

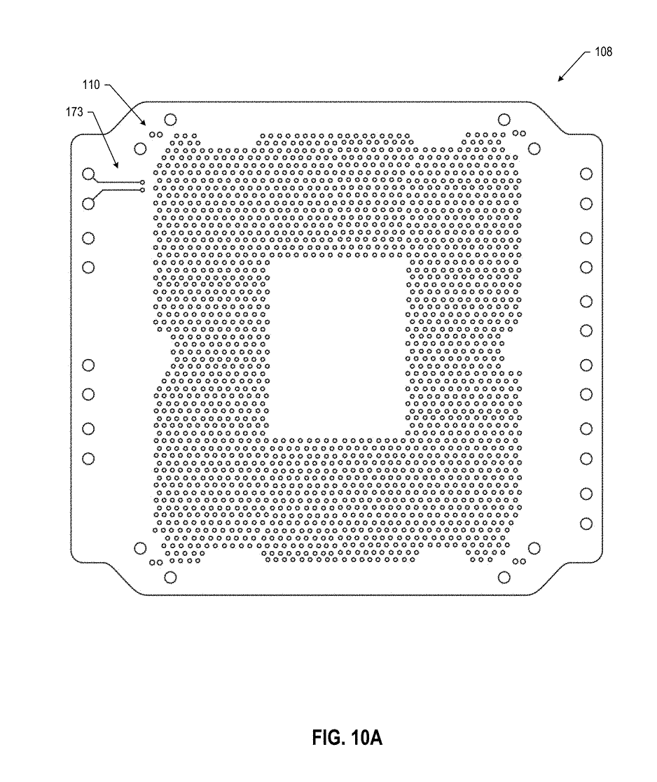

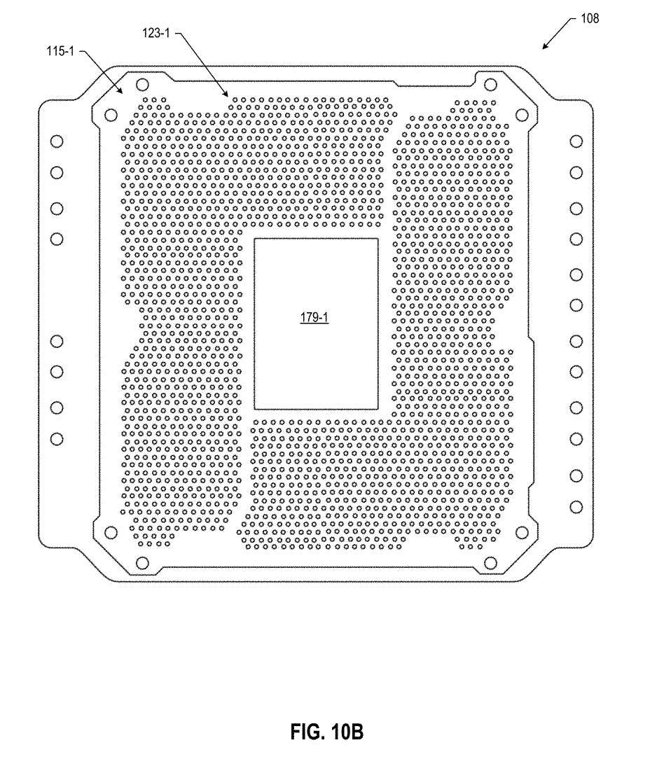

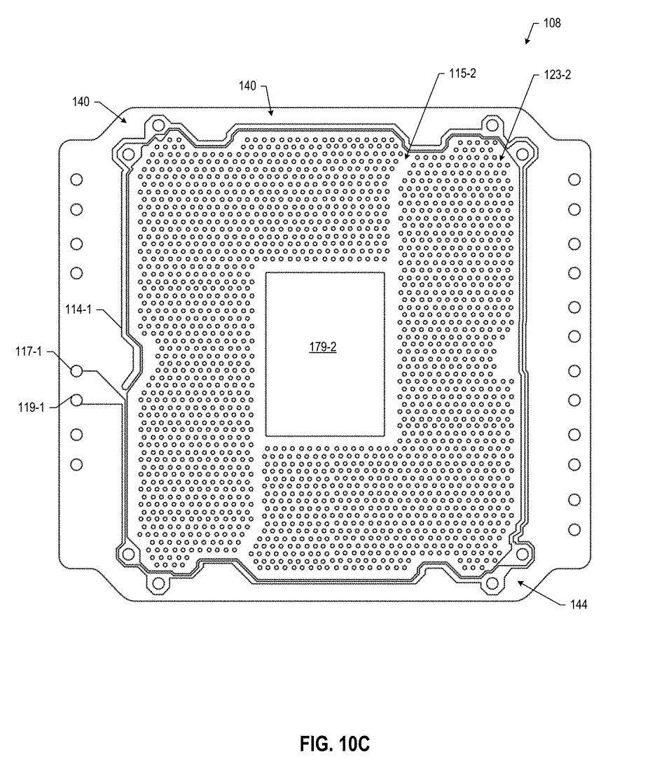

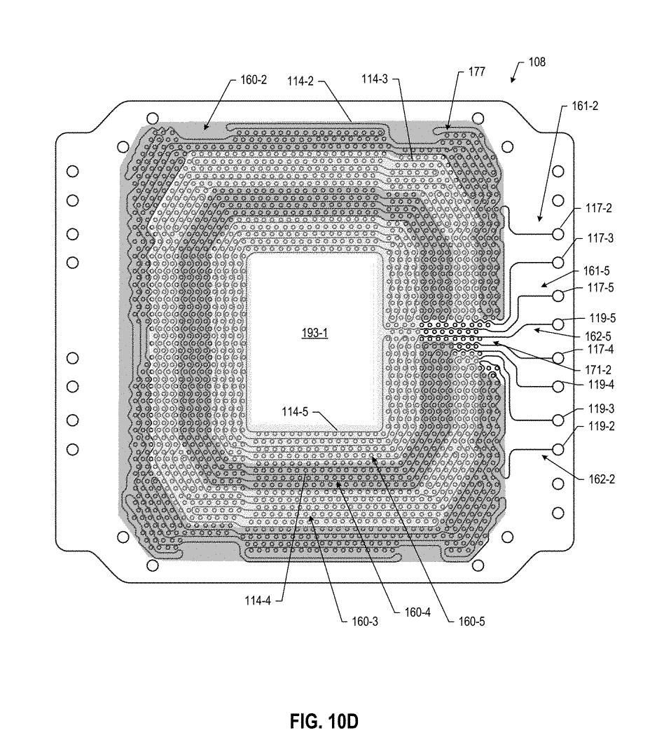

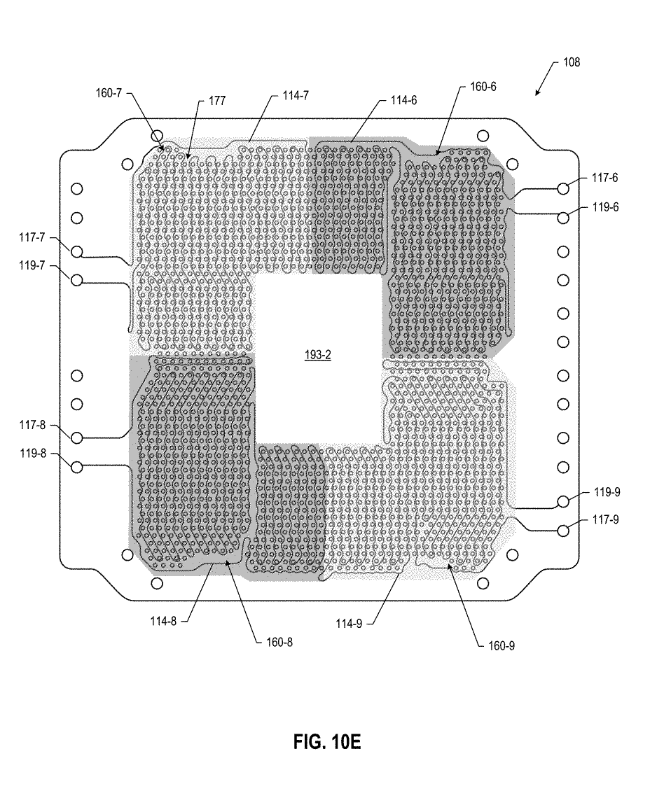

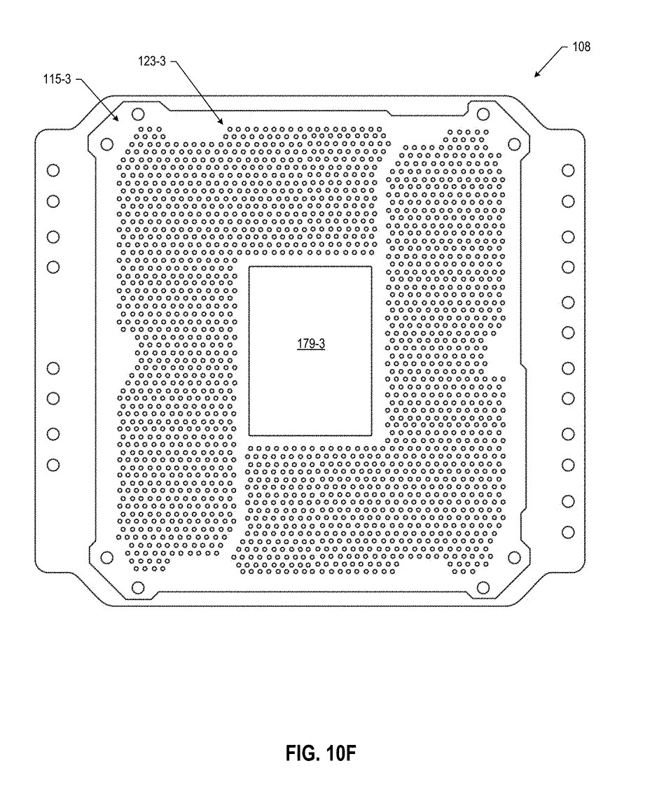

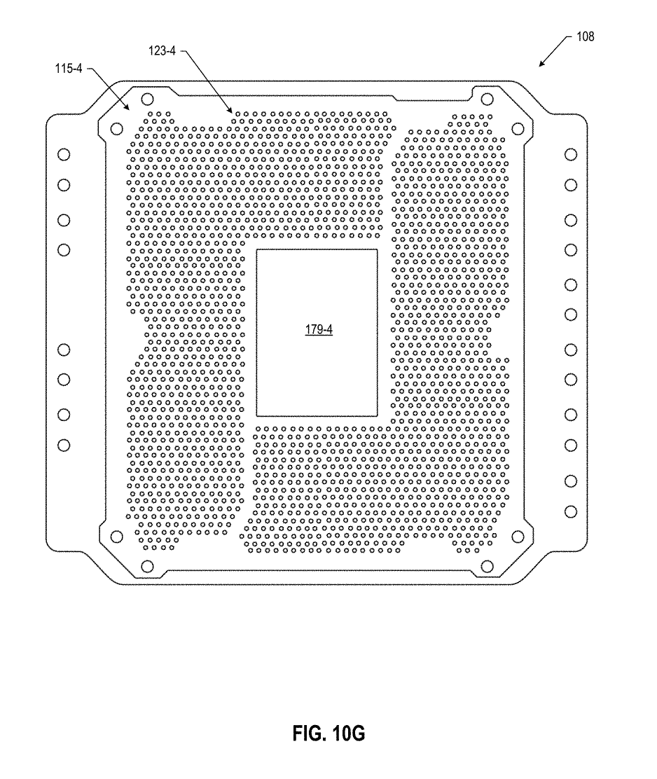

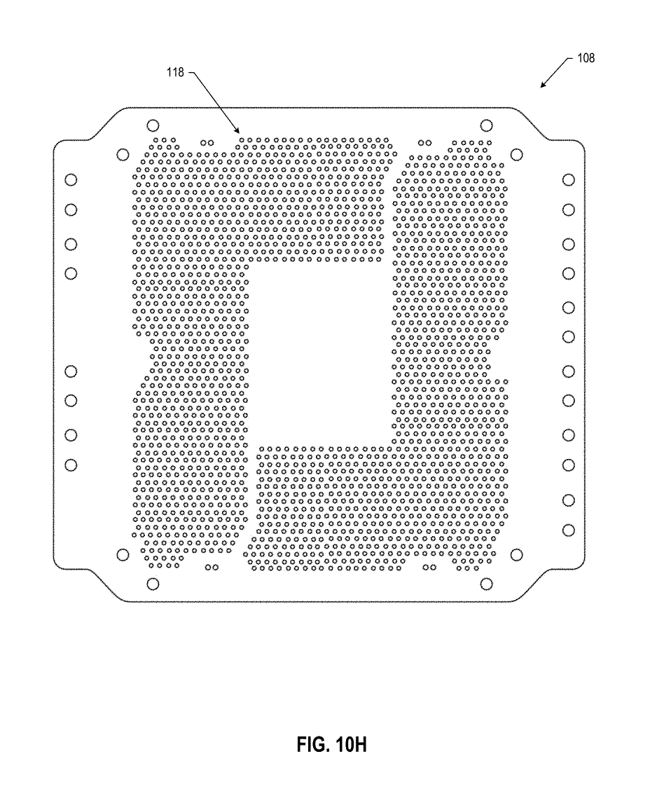

Heater traces 114 arranged in a regular pattern and having a convex footprint 160 (e.g., a rectangle) may help the IC package support structure 106 achieve a more uniform temperature than heater traces 114 having highly irregular footprints 160. Thus, for example, it may be advantageous to minimize the number of “openings” in the footprint 160 of a heater trace 114 through which other heater traces 114 extend. In particular, in some embodiments, a footprint 160 of a heater trace 114 may have no openings or only a single opening (e.g., as discussed below with reference to FIG. 10D). At the same time, it may be useful to have different heater traces 114 corresponding to different features in the IC package 100 in order to provide independently controllable heat for each of these different features. Selecting an appropriate heater trace arrangement 114 may be a balancing of these design features, as understood by one of skill in the art.

A design feature exhibited by the heater traces 114-1, 114-3, and 114-4 of FIG. 6 is the routing of a portion of the heater traces 114 outside of the area of the vias 177 and along the edges of the area 193-1 in which no vias 177 are disposed. These extra lengths of the heater traces 114 may mitigate the thermal gradient that forms in the IC package support structure 106 as one gets farther away from the vias 177, by generating additional heat to smooth the gradient. Generally, it may be advantageous to minimize the lengths of the connection terminal extensions 161 and 162 (between the connection terminals 117/119 and the footprint 160) for each heater trace 114, so as not to dissipate power (in the form of heat) in areas that have not been targeted for heating.

The footprints of different ones of the heater traces 114 included in different layers 108 of the IC package support structure 106 may overlap, or may not overlap. For example, in FIG. 6, the footprints 160 of the heater traces 114 do not overlap, although various ones of the connection terminal extensions 161 and 162 overlap with various ones of the footprints 160.

In some embodiments, when a heater trace 114 in one layer 108 “overlaps” a heater trace 114 in another layer 108, the overlapping portion of the heater traces 114 may have a greater width than the remainder of the heater traces 114. For example, the connection terminal extensions 161-3 and 162-3 of the heater trace 114-3 of FIG. 6 “overlaps” with the footprint 160-7 of the heater trace 114-7; in some embodiments, the connection terminal extensions 161-3 and 162-3 may have a width that is thicker than the width of the remainder of the heater trace 114-3 (e.g., by 1-5 mils). The width of the heater traces 114 may be limited by the pitch of the conductive contacts 110/vias 177, but increasing the width of a heater trace 114 in an overlap area may reduce the power dissipated by the thickened portion of the heater trace 114 relative to the non-thickened portion, preventing the formation of a hot spot where two heater traces 114 overlap.

In some embodiments of the IC package support structure 106 disclosed herein, a heater trace 114 may “wind” between adjacent parallel rows of vias 177. For example, in FIG. 6, the conductive contacts 110 include a first row 146-1 of vias 177, a second row 146-2 of vias 177, and the third row 146-3 of vias 177. The heater trace 114-4 is disposed between the first row 146-1 and the second row 146-2, and between the second row 146-2 and the third row 146-3. When heating an area of the IC package support structure 106, it may be advantageous to wind a heater trace 114 between adjacent vias 177, without “skipping” adjacent rows, to achieve a uniform temperature profile.

The density of vias 177 in a layer 108 of the IC package support structure 106 may vary across the layer 108. For example, in the embodiment of FIG. 6, the density of vias 177 proximate to the heater trace 114-1 (e.g., in the footprint 160-1 of the heater trace 114-1) is greater than the density of vias 177 proximate to the heater trace 114-4 (e.g., in the footprint 160-4 of the heater trace 114-4). As used herein, the “density” of vias 177 or conductive contacts 110 may refer to the percentage of area occupied by vias 177 or conductive contacts 110 in the layer 108 or the surface 105, respectively, of the IC package support structure. Because the vias 177 correspond to conductive pads 110 on the surface of the IC package support structure 106, and because heat may dissipate into the ambient environment from the conductive contacts 110, the IC package support structure 106 may experience greater thermal loss in regions with greater density of vias 177. Consequently, in some embodiments, the heater control device 130 may deliver more power to heater traces 114 in regions of higher density of vias 177. For example, the heater control device 130 may deliver more power to the heater trace 114-1 than to the heater trace 114-4.

In some embodiments of the IC package support structure 106 disclosed herein, different ones of multiple heater traces 114 may be disposed in a common layer 108, and/or in different layers 108. For example, as discussed in detail below with reference to FIGS. 7A-7E, the heater traces 114-1, 114-2, 114-3, and 114-4 may be included in a common layer 108, the heater traces 114-5 and 114-6 may be included in a common layer 108 (different from the layer 108 including the heater traces 114-1, 114-2, 114-3, and 114-4), and the heater traces 114-7 and 114-8 may be included in a common layer 108 (different from the layer including the heater traces 114-1, 114-2, 114-3, and 114-4, and different from the layer including the heater traces 114-5 and 114-6).

The stack of heater traces 114 represented in FIG. 6 may be implemented in any of a number of ways. FIGS. 7A-7E depict one particular arrangement of layers 108 in an IC package support structure 106 that may provide the heater trace stack of FIG. 6. In particular, FIG. 7A depicts an embodiment of a “top” layer 108, FIGS. 7B-7D depict embodiments of “intermediate” layers 108, and FIG. 7E depicts an embodiment of a “bottom” layer 108. In some embodiments, the layers 108 of FIGS. 7A-7E may be arranged adjacent to each other, in the depicted order, in the IC package support structure 106. An IC package support structure 106 that includes the layers 108 illustrated in FIGS. 7A-7E may also include other layers (e.g., insulator, metal plane, or signal trace layers) arranged in any order with the layers 108 of FIGS. 7A-7E. Additionally, the layers 108 illustrated in FIGS. 7A-7E may include signal traces and other features, as desired.

FIG. 7A depicts a “top” layer 108 in an IC package support structure 106, having conductive contacts 110 disposed thereon. The layer 108 of FIG. 7A may provide the second surface 105 of the IC package support structure 106. The conductive contacts 110 may be arranged in regions having different densities, as discussed above with reference to FIG. 6. For example, a region 164-1 (corresponding to the footprint 160-1 of the heater trace 114-1 of FIG. 6) of the conductive contacts 110 may have a greater density than a region 167-4 (corresponding to the footprint 160-4 of the heater trace 114-4 of FIG. 6). As discussed above, each of the conductive contacts 110 may be coupled to a via 177 (not shown) in the IC package support structure 106.

FIG. 7B depicts a layer 108 in an IC package support structure 106, including a metal plane 115-1. The metal plane 115-1 (and the other metal planes 115 disclosed herein) may be formed of any suitable material (e.g., copper) and may act as a heat spreader in the IC package support structure 106, as discussed above. The metal plane 115-1 may include holes 123-1 through which vias 177 (not shown) extend. In particular, the pattern of holes 123-1 in the metal plane 115-1 may match the pattern of conductive contacts 110 in the layer 108 of FIG. 7A and the pattern of vias 177 in FIG. 6. The holes 123-1 in the metal plane 115-1 (and the other metal planes 115 disclosed herein) may serve to space the metal plane 115-1 away from the vias 177, while still allowing the metal plane 115-1 to perform a heat-spreading function. The footprint of the metal plane 115-1 may be substantially rectangular, as shown. In particular, the footprint of the metal plane 115-1 may be substantially the same as the union of the footprints 160-1, 160-2, 160-3, and 160-4 of the heater traces 114-1, 114-2, 114-3, and 114-4 of FIG. 7C (discussed below) and the footprints 160-7 and 160-8 of the heater traces 114-7 and 114-8 of the layer 108 of FIG. 7D (discussed below). The layer 108 of FIG. 7B may also include the heater traces 114-5 and 114-6, and their respective first and second connection terminals 117 and 119. As discussed above with reference to FIG. 6, most of the length of the heater trace 114-6 is disposed at the corners 144 of the IC package support structure 106 (with some of the length of the heater trace 114-6 disposed along the edges 142 of the IC package support structure 106). Most of the length of the heater trace 114-5 is disposed along the edges 142 of the IC package support structure 106 (with some of the length of the heater trace 114-5 disposed at the corners 144 of the IC package support structure 106).

FIG. 7C depicts a layer 108 in an IC package support structure 106, including a metal plane 115-2. The layer 108 may include vias 177 in the central region 186, and the metal plane 115-2 may include holes 123-2 through which vias 177 (not shown) extend. In particular, the pattern of holes 123-2/vias 177 in the layer 108 of FIG. 7C may match the pattern of holes 123-1 in the layer 108 of FIG. 7B. The layer 108 of FIG. 7B may also include the heater traces 114-1, 114-2, 114-3, and 114-4, and their respective first and second connection terminals 117 and 119. The footprint of the metal plane 115-2 may be substantially ring-shaped, but may have “gaps” for the first and second connection terminal extensions 161 and 162, respectively, for each of the heater traces 114-1, 114-2, 114-3, and 114-4, to allow the heater traces 114 to reach the connection terminals 117 and 119 without making conductive contact with the metal plane 115-2.

FIG. 7D depicts a layer 108 in an IC package support structure 106, including a metal plane 115-3. The layer 108 may include vias 177 in the central region 186, and the metal plane 115-3 may include holes 123-3 through which vias 177 (not shown) extend. In particular, the pattern of holes 123-3/vias 177 in the layer 108 of FIG. 7D may match the pattern of holes 123-2 in the layer 108 of FIG. 7C. The footprint of the metal plane 115-3 may be substantially rectangular, as shown. In particular, the footprint of the metal plane 115-3 may be substantially the same as the union of the footprints 160-1, 160-2, 160-3, and 160-4 of the heater traces 114-1, 114-2, 114-3, and 114-4 of the layer 108 of FIG. 7C. The layer 108 of FIG. 7D may also include the heater traces 114-7 and 114-8, and their respective first and second connection terminals 117 and 119. The heater traces 114-6 and 114-7 are largely oriented along the edges 142, as illustrated and as discussed above with reference to FIG. 6. In particular, the union of the footprints 160-7 and 160-8 may be substantially the same as the footprint of the metal plane 115-2 of the layer 108 of FIG. 7C.

FIG. 7E depicts a “bottom” layer 108 in an IC package support structure 106, having conductive contacts 118 disposed thereon. The layer 108 of FIG. 7E may provide the first surface 107 of the IC package support structure 106. The conductive contacts 118 may be arranged in regions having different densities, as discussed above with reference to FIG. 7A. As discussed above, each of the conductive contacts 118 may be coupled to a “matching” via 177 (not shown) in the IC package support structure 106.

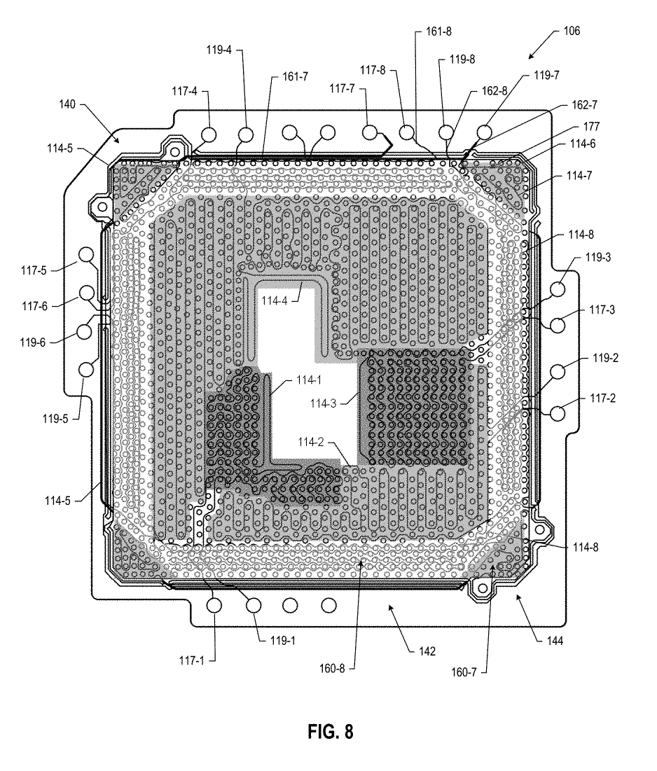

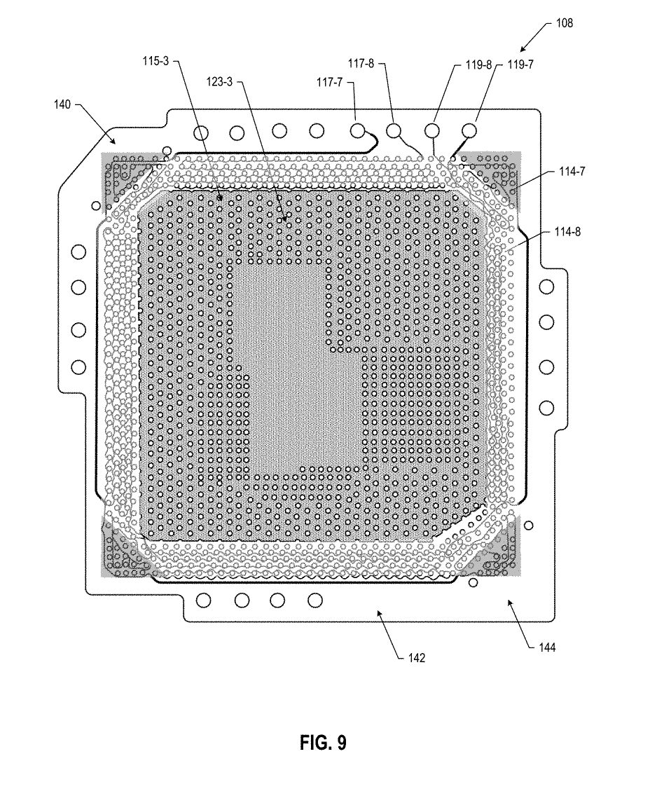

FIG. 8 is a top view of a stack of heater traces 114 disposed in multiple layers 108 of the IC package support structure 106. In some embodiments, the heater trace stack of FIG. 8 may be provided using the layers 108 of FIGS. 7A, 7B, 7C, and 7E along with the layer 108 of FIG. 9 (i.e., in lieu of the layer 108 of FIG. 7D as discussed above with reference to FIG. 6). In particular, the embodiment of FIG. 8 includes the heater traces 114-1, 114-2, 114-3, 114-4, 114-5, and 114-6 of FIG. 6 (also discussed above with reference to FIGS. 7B and 7C), and also includes heater traces 114-7 and 114-8 different from the heater traces 114-7 and 114-8 of FIG. 6. None of the heater traces 114 illustrated in FIG. 8 are conductively coupled to each other in the IC package support structure 106, and each of the heater traces 114 has a first connection terminal 117 and a second connection terminal 119. In the embodiment of FIG. 8, all of the connection terminals 117 and 119 are disposed in a perimeter region 140 of the IC package support structure 106. The central region 186 of the IC package support structure 106 may include vias 177, which may be coupled to corresponding ones of the conductive contacts 110.

The heater trace 114-7 of FIG. 8 has a footprint 160-7 shaped substantially as four triangles located at the corners 144 of the IC package support structure 106 (coupled together by lengths of the heater trace 114-7) with a first connection terminal extension 161-7 and a second connection terminal extension 162-7 extending from the footprint 160-7 to the connection terminals 117-7 and 119-7, respectively. The heater trace 114-8 of FIG. 8 has footprint 160-8 shaped substantially as four convex shapes disposed at the edges 142 of the IC package support structure 106 (coupled together by lengths of the heater trace 114-8) with a first connection terminal extension 161-8 and a second connection terminal extension 162-8 extending from the footprint 160-8 to the connection terminals 117-8 and 119-8, respectively. The layout of the heater traces 114-7 and 114-8 of FIG. 8 may be contrasted with the layout of the heater traces 114-7 and 114-8 of FIG. 6; in FIG. 6, the traces in “edge” and “corner” regions are combined and distributed between two “L” shaped heater traces 114-7 and 114-8. To simplify heat control by reducing the number of control stages, it may be advantageous in some cases to combine the “long” and “short” heater traces 114 into a single heater trace 114. The design of the heater traces 114-7 and 114-8 of FIG. 6 may represent an embodiment in which the relatively short “corner” regions (represented by the heater trace 114-7 of FIG. 8) are combined with the relatively longer “edge” regions (represented by the heater trace 114-8 of FIG. 8). In FIG. 8, the footprints 160 of the heater traces 114 do not overlap, although various ones of the connection terminal extensions 161 and 162 overlap with various ones of the footprints 160.

As discussed above with reference to FIG. 6, different ones of multiple heater traces 114 may be disposed in a common layer 108, and/or in different layers 108. For example, as discussed in detail above with reference to FIGS. 7B and 7C, the heater traces 114-1, 114-2, 114-3, and 114-4 of FIG. 8 may be included in a common layer 108, and the heater traces 114-5 and 114-6 of FIG. 8 may be included in a common layer 108 (different from the layer 108 including the heater traces 114-1, 114-2, 114-3, and 114-4). As discussed below with reference to FIG. 9, the heater traces 114-7 and 114-8 may be included in a common layer 108 (different from the layer 108 including the heater traces 114-1, 114-2, 114-3, and 114-4, and different from the layer 108 including the heater traces 114-5 and 114-6).

FIG. 9 depicts a layer 108 in an IC package support structure 106 that may have the stack of heater traces 114 illustrated in FIG. 8. In particular, an IC package support structure 106 including the stack of heater traces 114 illustrated in FIG. 8 may be provided using the layers 108 of FIGS. 7A, 7B, 7C, and 7E along with the layer 108 of FIG. 9 (i.e., in lieu of the layer 108 of FIG. 7D as discussed above with reference to FIG. 6). The layer 108 of FIG. 9 includes a metal plane 115-3. The layer 108 may include vias 177 in the central region 186, and the metal plane 115-3 may include holes 123-3 through which vias 177 (not shown) extend. In particular, the pattern of holes 123-3/vias 177 in the layer 108 of FIG. 9 may match the pattern of holes 123-2 in the layer 108 of FIG. 7C. The footprint of the metal plane 115-3 may be substantially rectangular, as shown. In particular, the footprint of the metal plane 115-3 may be substantially the same as the union of the footprints 160-1, 160-2, 160-3, and 160-4 of the heater traces 114-1, 114-2, 114-3, and 114-4 of the layer 108 of FIG. 7C, as discussed above with reference to FIG. 7D. The layer 108 of FIG. 9 may also include the heater traces 114-7 and 114-8, and their respective first and second connection terminals 117 and 119. The heater traces 114-6 and 114-7 are largely oriented along the edges 142 and the corners 144, as illustrated and as discussed above with reference to FIG. 8. In particular, the union of the footprints 160-6 and 160-7 may be substantially the same as the footprint of the metal plane 115-2 of the layer 108 of FIG. 7C.

FIGS. 10A-10H illustrate another example stack of layers 108 in an IC package support structure 106, in accordance with various embodiments. In particular, FIG. 10A depicts an embodiment of a “top” layer 108, FIGS. 10B-10G depict embodiments of “intermediate” layers 108, and FIG. 10H depicts an embodiment of a “bottom” layer 108. In some embodiments, the layers 108 of FIGS. 10A-10H may be arranged adjacent to each other, in that order, in the IC package support structure 106. An IC package support structure 106 that includes the layers 108 illustrated in FIGS. 10A-10H may also include other layers (e.g., insulator, metal plane, or signal trace layers) arranged in any order with the layers 108 of FIGS. 10A-10H. Additionally, the layers 108 illustrated in FIGS. 10A-10H may include signal traces and other features, as desired.

None of the heater traces 114 illustrated in FIGS. 10A-10H are conductively coupled to each other in the IC package support structure 106, and each of the heater traces 114 has a first connection terminal 117 and a second connection terminal 119. In the embodiment of FIGS. 10A-10H, all of the connection terminals 117 and 119 are disposed in a perimeter region 140 of the IC package support structure 106. Various layers 108 of FIGS. 10A-10H may include vias 177, which may be coupled to corresponding ones of the conductive contacts 110. As discussed above with reference to FIGS. 1-5, the conductive contacts 110 of the embodiment of FIGS. 10A-10H may be used to couple the IC package support structure 106 to one or more IC packages 100 (e.g., BGA IC packages 100). Heat generated by different ones of the heater traces 114 may be absorbed by proximate ones of the vias 177, and conducted to corresponding ones of the conductive contacts 110 to cause reflow of the solder 104, as discussed above.

FIG. 10A depicts a “top” layer 108 in an IC package support structure 106, having conductive contacts 110 disposed thereon. The layer 108 of FIG. 10A may provide the second surface 105 of the IC package support structure 106. In the embodiment illustrated in FIG. 10A, the conductive contacts 110 may have substantially uniform density (in contrast to the embodiment discussed above with reference to FIG. 7A). As discussed above, each of the conductive contacts 110 may be coupled to a via 177 (not shown) in the IC package support structure 106. FIG. 10A also depicts traces 173 that run to a thermistor component (e.g., a surface-mounted component, not shown), which may be probed by a controller to determine an initial temperature for the IC package support structure 106 for temperature sensor calibration.

FIG. 10B depicts a layer 108 in an IC package support structure 106, including a metal plane 115-1. The metal plane 115-1 may include holes 123-1 through which vias 177 (not shown) extend. In particular, the pattern of holes 123-1 in the metal plane 115-1 may match the pattern of conductive contacts 110 in the layer 108 of FIG. 10A. The footprint of the metal plane 115-1 may be substantially rectangular with a rectangular opening 179-1 (which may, for example, correspond to an area in which there are no vias 177), as shown.

FIG. 10C depicts a layer 108 in an IC package support structure 106, including a metal plane 115-2. The metal plane 115-2 may include holes 123-2 through which vias 177 (not shown) extend. In particular, the pattern of holes 123-2 in the metal plane 115-2 may match the pattern of conductive contacts 110 in the layer 108 of FIG. 10A (and the pattern of holes 123-1 in the layer 108 of FIG. 10B). Metal planes 115 may be included in the layers 108 depicted in both FIG. 10B and FIG. 10C so as to achieve a desired total thickness of metal without having to make the thickness of any one metal plane 115 so large that the heater traces 114 that share a layer with the metal plane 114 require excessive current to generate the desired amount of heat, as discussed above with reference to FIG. 1. The footprint of the metal plane 115-2 may be substantially rectangular with a rectangular opening 179-2 (which may, for example, correspond to an area in which there are no vias 177), as shown. In particular, the footprint of the metal plane 115-2 may be substantially the same as the union of the footprints 160-2, 160-3, 160-4, and 160-5 of the heater traces 114-2, 114-3, 114-4, and 114-5 of FIG. 10D (discussed below). The layer 108 of FIG. 10C may also include the heater trace 114-1, and its respective first and second connection terminals 117 and 119. The heater trace 114-1 may be disposed in the perimeter region 140, traveling along the edges 142 and the corners 144 of the IC package support structure 106, and wrapping around the metal plane 115-2.

FIG. 10D depicts a layer 108 of an IC package support structure 106, including multiple heater traces 114. In particular, the heater traces 114-2, 114-3, 114-4, and 114-5 may be arranged concentrically around an area 193-1 in which there are no vias 177 (e.g., as discussed above with reference to the openings 179). Each of the heater traces 114 in the embodiment of FIG. 10D may include a first connection terminal 117 and a second connection terminal 119. Each of the heater traces 114 illustrated in the embodiment of FIG. 10D may have a footprint 160 (indicated by shading). Connection terminal extensions of each heater trace 114 may extend away from the footprint 160 to provide the connection terminals 117 and 119. In the embodiment illustrated in FIG. 10D, the heater traces 114-2, 114-3, 114-4, and 114-5 each extend around the area 193 in a concentric manner, enabling the temperature gradient of the IC package support structure 106 around the area 193 to be controlled by controlling the heat delivered by each of the heater traces 114. The heater control device 130 may provide the concentric heater traces 114 of FIG. 10D with power to reduce the concentric temperature gradient that naturally forms when heating a flat object (e.g., the IC package 100).

In some embodiments of the IC package support structures 106 disclosed herein, a footprint 160 of a heater trace 114 may have an opening through which the connection terminal extensions 161 and 163 of another heater trace 114 extend. For example, the footprint 160-2 of the heater trace 114-2 of the embodiment of FIG. 10D has an opening 171-2 through which the connection terminal extensions 161-5 and 162-5 of the heater trace 114-5 extend. Other footprints 160 of other heater traces 114 disclosed herein may also include opening through which the connection terminal extensions of other heater traces extend (e.g., the footprint of the heater trace 114-5 of FIG. 6 has an opening through which the connection terminal extensions of the heater trace 114-6 extend), but these are not labeled in the FIGS. for ease of illustration.

FIG. 10E depicts a layer 108 of an IC package support structure 106, including multiple heater traces 114. In particular, the heater traces 114-6, 114-7, 114-8, and 114-9 may be arranged in “quadrants” around an area 193-2 in which there are no vias 177 (e.g., as discussed above with reference to FIG. 10D). Each of the heater traces 114 in the embodiment of FIG. 10E may have a footprint 160 shaped substantially as an “L,” with first connection terminal extensions and second connection terminal extensions extending from the footprint 160 to the connection terminals 117 and 119, respectively. The “quadrant” layout of the heater traces 114 of FIG. 10E may modulate power delivery, and may improve the thermal match between the IC package support structure 106 and the PCB 116 when the IC package support structure 106 is an interposer. When the layers 108 of FIGS. 10D and 10E are stacked, the footprints 160 of different ones of the heater traces 114 included in FIG. 10D will overlap with the footprints 160 of different ones of the heater traces 114 included in FIG. 10E.

FIG. 10F depicts a layer 108 in an IC package support structure 106, including a metal plane 115-3. The metal plane 115-3 may include holes 123-3 through which vias 177 (not shown) extend. In particular, the pattern of holes 123-3 in the metal plane 115-3 may match the pattern of conductive contacts 110 in the layer 108 of FIG. 10A. The footprint of the metal plane 115-3 may be substantially rectangular with a rectangular opening 179-3 (which may, for example, correspond to an area in which there are no vias 177), as shown.

FIG. 10G depicts a layer 108 in an IC package support structure 106, including a metal plane 115-4. The metal plane 115-4 may include holes 123-4 through which vias 177 (not shown) extend. In particular, the pattern of holes 123-4 in the metal plane 115-4 may match the pattern of conductive contacts 110 in the layer 108 of FIG. 10A. The footprint of the metal plane 115-4 may be substantially rectangular with a rectangular opening 179-4 (which may, for example, correspond to an area in which there are no vias 177), as shown. In some embodiments, it may be advantageous for the metal planes 115 in an IC package support structure 106 to be arranged symmetrically around a core of the IC package support structure 106 to minimize warpage of the IC package support structure 106; in such an embodiment, the metal plane 115-4 may serve as the complement of the metal plane 115-1 of FIG. 106.

FIG. 10H depicts a “bottom” layer 108 in an IC package support structure 106, having conductive contacts 118 disposed thereon. The layer 108 of FIG. 10H may provide the first surface 107 of the IC package support structure 106. As discussed above, each of the conductive contacts 118 may be coupled to a “matching” via 177 (not shown) in the IC package support structure 106.

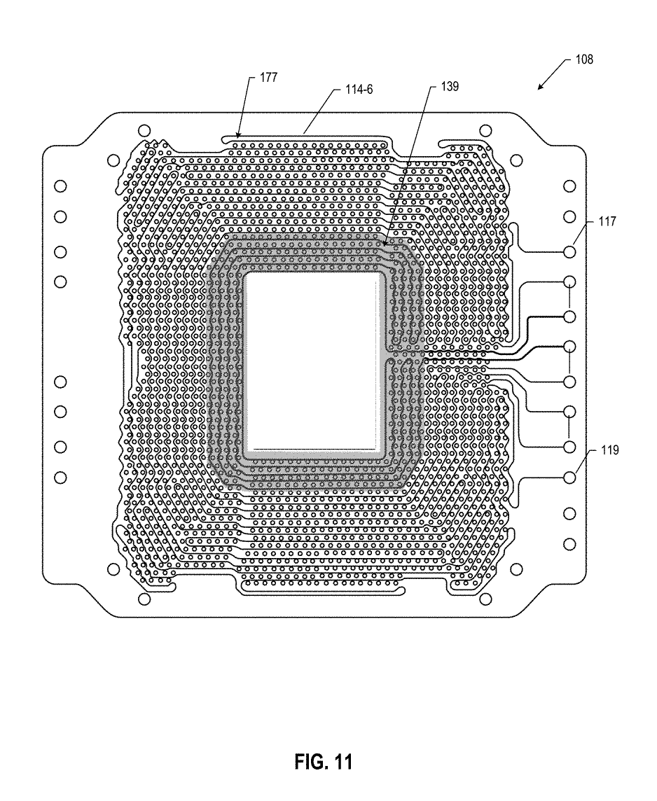

In some embodiments, different portions of a single heater trace 114 may have different widths. The amount of power dissipated in a portion of a heater trace 114 may be inverse to the width of that portion, and thus thicker portions of the heater trace 114 may dissipate less power than thinner portions. For example, FIG. 11 illustrates an embodiment in which a portion 139 of a single heater trace 114 (having connection terminals 117 and 119, and proximate to vias 177) has a width that is greater than the width of the remainder of the heater trace 114, as shown. The routing of the heater trace 114 of FIG. 11 may be substantially identical to the routing of the union of the heater traces 114-2, 114-3, 114-4, and 114-5 of FIG. 10D. The thickened portion 139 may dissipate less power (in the form of heat) than the remainder of the heater trace 114, enabling the creation of multiple zones of varying power dissipation with a single heater trace 114. Only a single thickened portion 139 is illustrated in FIG. 11, but any number of thickened portions, having any appropriate thicknesses, may be used. In some embodiments, the thickened portion 139 may have a width of 7-8 mils, while the remainder of the heater trace 114 may have a width of 4-5 mils.

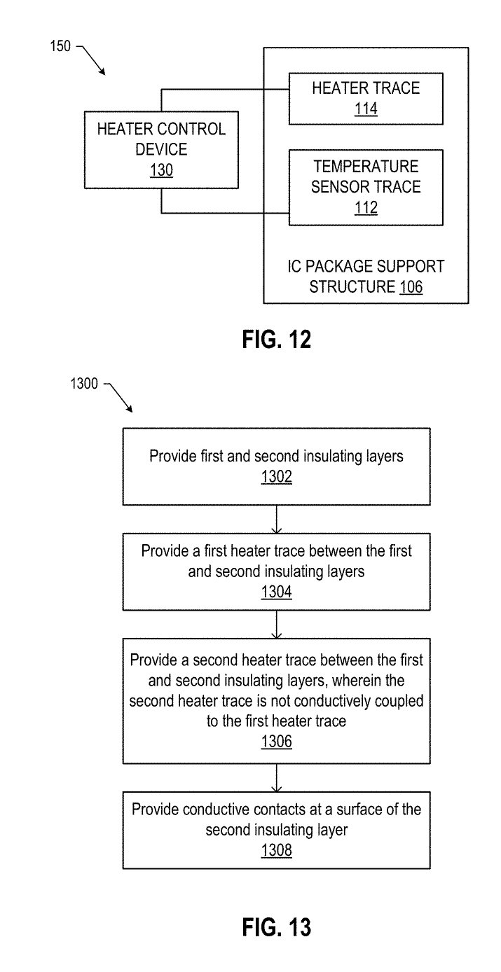

The heater traces 114 and/or the temperature sensor traces 112 of an IC package support structure 106 may be used in a reflow control system 150 to monitor and/or control the reflow of the solder 104. FIG. 12 is a block diagram of a reflow control system 150, in accordance with various embodiments. The system 150 may include one or more heater traces 114 of the IC package support structure 106, coupled to a heater control device 130 to control power provided to the heater trace 114. The heater control device 130 may be implemented using any controller device and technique known in the art (e.g., a programmed microcontroller).

In some embodiments, the system 150 may further include one or more temperature sensor traces 112, coupled to the heater control device 130. In such embodiments, the heater control device 130 may be configured to measure the resistance of the temperature sensor trace 112 and thereby determine the equivalent temperature of the temperature sensor trace 112, as discussed above. The heater control device 130 may then control the power provided to the heater traces 114 based on the equivalent temperature (e.g., increasing the power when the equivalent temperature is below a desired temperature, and vice versa). The heater traces 114 and the heater control device 130 may be configured to limit the heat generated by the heater traces 114 to avoid accidentally reflowing any solder other than that targeted for reflow, or otherwise exceeding any thermal constraints of the IC package assembly 120.

The IC package support structures 106 disclosed herein may be manufactured using any suitable method. For example, FIG. 13 is a flow diagram of a method 1300 of manufacturing an IC package support structure, in accordance with various embodiments. While the operations of the method 1300 are arranged in a particular order in FIG. 13 and illustrated once each, in various embodiments, one or more of the operations may be repeated or performed in parallel (e.g., when multiple IC package support structures are being manufactured). Operations discussed below with reference to the method 1300 may be illustrated with reference to the IC package support structure 106 of FIG. 1, but this is simply for ease of discussion, and the method 1300 may be used to manufacture any suitable IC package support structure.

At 1302, first and second insulating layers may be provided. For example, the insulating layer 108-1 and the insulating layer 108-9 of the IC package support structure 106 may be provided as part of a substrate (e.g., PCB) manufacturing procedure, as known in the art.

At 1304, a first heater trace may be provided between the first and second insulating layers of 1302. For example, a first heater trace 114 (e.g., any of the heater traces 114-1, 114-2, and 114-3 of FIG. 1) may be provided between the insulating layer 108-1 and the insulating layer 108-2. The operations discussed above with reference to 1302 and 1304 may be performed as part of a substrate manufacturing procedure wherein different layers of the IC package support structure are formed in sequence. In particular, the provision of the first and second insulating layers at 1302 may not occur before the provision of the first heater trace at 1304; instead, one of the insulating layers may be provided, the first heater trace may be subsequently provided, and the other of the insulating layers may be subsequently provided.

At 1306, a second heater trace may be provided between the first and second insulating layers of 1302. The second heater trace (provided at 1306) may not be conductively coupled to the first heater trace (provided at 1304). For example, the first and second heater traces may be any two different ones of the heater traces 114 of FIG. 1. The provision of the first and second insulating layers at 1302 may not necessarily occur before the provision of the second heater trace; instead, one of the insulating layers may be provided, the first and second heater traces may be subsequently provided, and the other of the insulating layers may be subsequently provided.

At 1308, conductive contacts may be provided on a surface of the second insulating layer. For example, the conductive contacts 110 may be provided on the insulating layer 108-1.

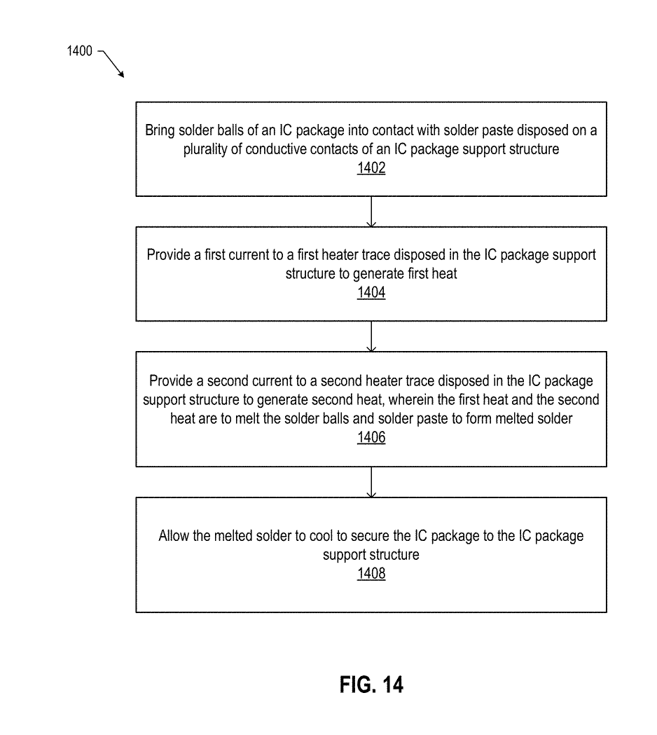

The IC package assemblies 120 disclosed herein may be manufactured using any suitable method. For example, FIG. 14 is a flow diagram of a method 1400 of attaching IC packages to an IC package support structure (e.g., during the manufacturing an IC package assembly), in accordance with various embodiments. While the operations of the method 1400 are arranged in a particular order in FIG. 14 and illustrated once each, in various embodiments, one or more of the operations may be repeated or performed in parallel (e.g., when multiple IC package assembly are being manufactured). Operations discussed below with reference to the method 1400 may be illustrated with reference to the assemblies 200 and 300 of FIGS. 4 and 5, respectively, but this is simply for ease of discussion, and the method 1400 may be used to manufacture any suitable IC package assembly.

At 1402, first solder balls of a first IC package be brought into contact with first solder paste disposed on the first plurality of conductive contacts of an IC package support structure. For example, the solder balls 134 of the IC package 100-1 may be brought into contact with the solder paste 132 disposed on the conductive contacts 110-1 of the IC package support structure 106, as discussed above with reference to FIG. 4.

At 1404, a first power may be provided to a first heater trace disposed in the IC package support structure to generate first heat. For example, a power may be provided to one of the heater traces 114 included in the IC package support structure 106 to generate heat.

At 1406, a second power may be provided to a second heater trace disposed in the IC package support structure to generate second heat. For example, a power may be provided to a different one of the heater traces 114 in the IC package support structure 106 (i.e., different from the heater trace to which the first power was provided at 1404) to generate heat. The first heat (generated at 1404) and the second heat (generated at 1406) may melt the solder balls and solder paste of 1402 to form melted solder.

At 1408, the melted solder may be allowed to cool to secure the IC package to the IC package support structure. For example, the solder 104-1 may be formed by cooling the melted solder balls 134 and solder paste 132, as discussed above with reference to FIGS. 4 and 5.

FIG. 15 is a block diagram of an example computing device 500 that may include an IC package support structure 106 in accordance with the teachings of the present disclosure. In particular, any of the components of the computing device 500 that may be implemented at least partially in an IC package may be disposed on the IC package support structure 106. Alternatively or additionally, any of the components of the computing device 500 that may be secured to a substrate may be secured to the IC package support structure 106. A number of components are illustrated in FIG. 15 as included in the computing device 500, but any one or more of these components may be omitted or duplicated, as suitable for the application. In some embodiments, some or all of these components are fabricated onto a single system-on-a-chip (SoC) die (e.g., included in an IC package 100).

Additionally, in various embodiments, the computing device 500 may not include one or more of the components illustrated in FIG. 15, but the computing device 500 may include interface circuitry for coupling to the one or more components. For example, the computing device 500 may not include a display device 506, but may include display device interface circuitry (e.g., a connector and driver circuitry) to which a display device 506 may be coupled. In another set of examples, the computing device 500 may not include an audio input device 524 or an audio output device 508, but may include audio input or output device interface circuitry (e.g., connectors and supporting circuitry) to which an audio input device 524 or audio output device 508 may be coupled. Any one or more of the components of the computing device 500 may include one or more IC package support structures 106.

The computing device 500 may include a processing device 502 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. In some embodiments, the processing device 502 may be included in an IC package assembly 120 (e.g., in an IC package 100). The computing device 500 may include a memory 504, which may itself include one or more memory devices such as volatile memory (e.g., dynamic random access memory (DRAM)), non-volatile memory (e.g., read-only memory (ROM)), flash memory, solid state memory, and/or a hard drive. In some embodiments, the memory 504 may include memory that shares a die with the processing device 502. This memory may be used as cache memory and may include embedded DRAM (eDRAM) or spin transfer torque magnetic RAM (STT-MRAM). The memory 504 may be included in an IC package assembly 120 (e.g., secured to the IC package support structure 106).

In some embodiments, the computing device 500 may include a communication chip 512 (e.g., one or more communication chips). For example, the communication chip 512 may be configured for managing wireless communications for the transfer of data to and from the computing device 500. The term “wireless” and its derivatives may be used to describe circuits, devices, systems, methods, techniques, communication channels, etc., that may communicate data through the use of modulated electromagnetic radiation through a nonsolid medium. The term does not imply that the associated devices do not contain any wires, although in some embodiments they might not. The communication chip 512 may be included in the IC package assembly 120.

The communication chip 512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 512 may operate in accordance with other wireless protocols in other embodiments. The computing device 500 may include an antenna 522 to facilitate wireless communications and/or to receive other wireless communications (such as AM or FM radio transmissions).

In some embodiments, the communication chip 512 may manage wired communications, such as electrical, optical, or any other suitable communication protocols (e.g., the Ethernet). As noted above, the communication chip 512 may include multiple communication chips. For instance, a first communication chip 512 may be dedicated to shorter-range wireless communications such as Wi-Fi or Bluetooth, and a second communication chip 512 may be dedicated to longer-range wireless communications such as GPS, EDGE, GPRS, CDMA, WiMAX, LTE, EV-DO, or others. In some embodiments, a first communication chip 512 may be dedicated to wireless communications, and a second communication chip 512 may be dedicated to wired communications.

The computing device 500 may include battery/power circuitry 514. The battery/power circuitry 514 may include one or more energy storage devices (e.g., batteries or capacitors) and/or circuitry for coupling components of the computing device 500 to an energy source separate from the computing device 500 (e.g., AC line power). Some or all of the battery/power circuitry 514 may be secured to the IC package support structure 106, as noted above.

The computing device 500 may include a display device 506 (or corresponding interface circuitry, as discussed above). The display device 506 may include any visual indicators, such as a heads-up display, a computer monitor, a projector, a touchscreen display, a liquid crystal display (LCD), a light-emitting diode display, or a flat panel display, for example.

The computing device 500 may include an audio output device 508 (or corresponding interface circuitry, as discussed above). The audio output device 508 may include any device that generates an audible indicator, such as speakers, headsets, or earbuds, for example.

The computing device 500 may include an audio input device 524 (or corresponding interface circuitry, as discussed above). The audio input device 524 may include any device that generates a signal representative of a sound, such as microphones, microphone arrays, or digital instruments (e.g., instruments having a musical instrument digital interface (MIDI) output).

The computing device 500 may include a global positioning system (GPS) device 518 (or corresponding interface circuitry, as discussed above). The GPS device 518 may be in communication with a satellite-based system and may receive a location of the computing device 500, as known in the art. Some or all of the GPS device 518 may be secured to the IC package support structure 106, as noted above.

The computing device 500 may include an other output device 510 (or corresponding interface circuitry, as discussed above). Examples of the other output device 510 may include an audio codec, a video codec, a printer, a wired or wireless transmitter for providing information to other devices, or an additional storage device.

The computing device 500 may include an other input device 520 (or corresponding interface circuitry, as discussed above). Examples of the other input device 520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 500 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 500 may be any other electronic device that processes data.

The following paragraphs provide various examples of the embodiments disclosed herein.

Example 1 is an integrated circuit (IC) package support structure, including: a first heater trace; and a second heater trace, wherein the second heater trace is not conductively coupled to the first heater trace in the IC package support structure.

Example 2 may include the subject matter of Example 1, and may further specify that the first heater trace has a footprint and first and second connection terminal extensions, and the first footprint is a convex shape.

Example 3 may include the subject matter of Example 2, and may further specify that the footprint is a rectangle.

Example 4 may include the subject matter of any of Examples 2-3, and may further specify that the footprint is a first footprint, and the second heater trace has a second footprint with an opening through which the connection terminal extensions of the first heater trace extend.

Example 5 may include the subject matter of any of Examples 1-4, and may further specify that the first heater trace includes a serpentine portion.

Example 6 may include the subject matter of any of Examples 1-5, and may further specify that the first heater trace weaves between vias in a row of vias.

Example 7 may include the subject matter of any of Examples 1-6, and may further specify that the first heater trace is disposed in a perimeter region of the IC package support structure.

Example 8 may include the subject matter of Example 7, and may further specify that the first heater trace is disposed along an edge of the IC package support structure.

Example 9 may include the subject matter of any of Examples 1, and may further include a central region having vias disposed therein; wherein the first heater trace does not extend into the central region.

Example 10 may include the subject matter of Example 7, and may further specify that the first heater trace is disposed at a corner of the IC package support structure.

Example 11 may include the subject matter of Example 10, and may further specify that the first heater trace is also disposed along an edge of the IC package support structure.

Example 12 may include the subject matter of any of Examples 1-11, and may further include first, second, and third parallel rows of vias; wherein the second row of vias is disposed between the first and third rows of vias, the first heater trace is disposed between the first and second rows of vias, and the first heater trace is disposed between the first and third rows of vias.

Example 13 may include the subject matter of any of Examples 1-12, and may further specify that the first heater trace includes a first portion having a first width and a second portion having a second width different from the first width.

Example 14 may include the subject matter of Example 13, and may further specify that the first width is greater than the second width, and a footprint of the second portion of the first heater trace wraps around a footprint of the first portion of the first heater trace.

Example 15 may include the subject matter of any of Examples 1-14, and may further specify that a footprint of the first heater trace wraps around a footprint of the second heater trace.

Example 16 may include the subject matter of any of Examples 1-15, and may further specify that the first heater trace is disposed in a first layer of the IC package support structure, and the second heater trace is disposed in a second layer, different from the first layer, of the IC package support structure.

Example 17 may include the subject matter of Example 16, and may further specify that a footprint of the first heater trace does not overlap with a footprint of the second heater trace.

Example 18 may include the subject matter of Example 16, and may further specify that a footprint of the first heater trace overlaps with a footprint of the second heater trace.

Example 19 may include the subject matter of Example 18, and may further specify that a first portion of the first heater trace is disposed in an area in which the footprint of the first heater trace overlaps with the footprint of the second heater trace, a second portion of the first heater trace is disposed in an area in which the footprint of the first heater trace does not overlap the footprint of the second heater trace, and a width of the first portion of the first heater trace is greater than a width of the second portion of the first heater trace.

Example 20 may include the subject matter of any of Examples 16-19, and may further include a metal plane disposed in a third layer of the IC package support structure, wherein the third layer is different from the first and second layers and the IC package support structure does not include conductive contacts to the metal plane.

Example 21 may include the subject matter of Example 20, and may further specify that the metal plane includes a plurality of holes.

Example 22 may include the subject matter of any of Examples 1-21, and may further specify that the IC package support structure is an interposer.

Example 23 may include the subject matter of any of Examples 1-21, and may further specify that the IC package support structure is a motherboard.

Example 24 may include the subject matter of any of Examples 1-23, and may further specify that the IC package support structure is a printed circuit board.

Example 25 may include the subject matter of any of Examples 1-24, and may further include: conductive contacts; and a ball grid array (BGA) package coupled to the conductive contacts via solder.

Example 26 may include the subject matter of Example 25, and may further specify that the first heater trace is disposed in the IC package support structure to, when a first power is dissipated in the first heater trace, generate heat to melt the solder.

Example 27 may include the subject matter of any of Examples 1-26, and may further include: a first region of vias proximate to the first heater trace; and a second region of vias proximate to the second heater trace.

Example 28 may include the subject matter of Example 27, and may further specify that a density of the vias in the first region is greater than a density of the vias in the second region.

Example 29 may include the subject matter of Example 28, and may further include a heater control device in conductive contact with the first heater trace and the second heater trace; wherein the heater control device is to deliver more power to the first heater trace than the second heater trace.

Example 30 may include the subject matter of any of Examples 27-29, and may further specify that the first heater trace is disposed in the IC package support structure to, when a first power is dissipated in the first heater trace, generate heat to melt solder disposed on conductive contacts coupled to the vias in the first region without melting solder disposed on conductive contacts coupled to the vias in the second region.

Example 31 may include the subject matter of Example 30, and may further specify that the second heater trace is disposed in the IC package support structure to, when a second power is dissipated in the second heater trace, generate heat to melt solder disposed on conductive contacts coupled to the vias in the second region without melting solder disposed on conductive contacts coupled to the vias in the first region.

Example 32 is a computing device, including: an integrated circuit (IC) package support structure, including a first heater trace, a second heater trace, wherein the second heater trace is not conductively coupled to the first heater trace in the IC package support structure, and a plurality of conductive contacts disposed at a surface of the IC package support structure; and an IC package conductively coupled to the plurality of conductive contacts.

Example 33 may include the subject matter of Example 32, and may further specify that the IC package is a central processing unit (CPU) package.

Example 34 may include the subject matter of any of Examples 32-33, and may further specify that the IC package is a ball grid array (BGA) package, and the IC package is conductively coupled to the plurality of conductive contacts via solder.

Example 35 may include the subject matter of any of Examples 32-34, and may further specify that the plurality of conductive contacts includes a first plurality of conductive contacts and a second plurality of conductive contacts, the first heater trace is proximate to vias coupled to the first plurality of conductive contacts, the second heater trace is proximate to vias coupled to the second plurality of conductive contacts, and the first and second pluralities of conductive contacts have different densities.

Example 36 may include the subject matter of any of Examples 32-35, and may further specify that the IC package support structure is an interposer, and the computing device further comprises:

a motherboard conductively coupled to the interposer such that the interposer is disposed between the IC package and the motherboard.

Example 37 may include the subject matter of any of Examples 32-35, and may further specify that the IC package support structure is a motherboard.

Example 38 may include the subject matter of any of Examples 32-37, and may further specify that the first heater trace is disposed in the IC package support structure to, when a first power is dissipated in the first heater trace, generate heat to melt solder disposed on the plurality of conductive contacts.

Example 39 may include the subject matter of any of Examples 32-38, and may further include a memory device.

Example 40. The computing device of claim 32, and may further include a display device.

Example 41 is a method of manufacturing an integrated circuit (IC) package support structure, including: providing first and second insulating layers; providing a first heater trace between the first and second insulating layers; providing a second heater trace between the first and second insulating layers, wherein the second heater trace is not conductively coupled to the first heater trace; and providing conductive contacts at a surface of the second insulating layer.

Example 42 may include the subject matter of Example 41, and may further include providing a third insulating layer, wherein the third insulating layer is disposed between the first heater trace and the second heater trace.

Example 43 may include the subject matter of any of Examples 41-42, and may further include: providing signal routing traces between the first and second insulating layers; and providing vias to conductively couple the conductive contacts and the signal routing traces.

Example 44 may include the subject matter of any of Examples 41-43, and may further include: providing a metal plane between the first and second insulating layers; and providing power and ground contacts; wherein the metal plane is not conductively coupled to the power or ground contacts.

Example 45 may include the subject matter of any of Examples 41-44, and may further include providing solder paste to the conductive contacts.

Example 46 is a method of manufacturing an integrated circuit (IC) package assembly, including: bringing solder balls of an IC package into contact with solder paste disposed on a plurality of conductive contacts of an IC package support structure; providing a first power to a first heater trace disposed in the IC package support structure to generate first heat; providing a second power to a second heater trace disposed in the IC package support structure to generate second heat, wherein the first heat and the second heat are to melt the solder balls and solder paste to form melted solder; and allowing the melted solder to cool to secure the IC package to the IC package support structure.

Example 47 may include the subject matter of Example 46, and may further specify that the IC package includes a processing device.

Example 48 may include the subject matter of any of Examples 46-47, and may further specify that the first power is provided to the first heater trace by a heater control device brought into temporary conductive contact with the first heater trace.

Example 49 may include the subject matter of any of Examples 46-48, and may further include, after allowing the melted solder to cool to secure the IC package to the IC package support structure, providing a third power to the first heater trace and a fourth power to the second heater trace to melt the cooled solder.

Example 50 may include the subject matter of Example 49, and may further include, after providing the third power to the first heater trace and the fourth power to the second heater trace to generate heat to melt the cooled solder, removing the IC package from contact with the IC package support structure.

What is claimed is:

1. An integrated circuit (IC) package support structure, comprising:
a first heater trace; and
a second heater trace, wherein the second heater trace is not conductively coupled to the first heater trace in the IC package support structure.

2. The IC package support structure of claim 1, wherein the first heater trace has a footprint and first and second connection terminal extensions, and the first footprint is a convex shape.

3. The IC package support structure of claim 2, wherein the footprint is a first footprint, and the second heater trace has a second footprint with an opening through which the connection terminal extensions of the first heater trace extend.

4. The IC package support structure of claim 1, wherein the first heater trace includes a serpentine portion.

5. The IC package support structure of claim 1, wherein the first heater trace is disposed in a perimeter region of the IC package support structure.

6. The IC package support structure of claim 1, further comprising:
a central region having vias disposed therein;
wherein the first heater trace does not extend into the central region.

7. The IC package support structure of claim 1, wherein the first heater trace includes a first portion having a first width and a second portion having a second width different from the first width.

8. The IC package support structure of claim 1, wherein a footprint of the first heater trace wraps around a footprint of the second heater trace.

9. The IC package support structure of claim 1, wherein the first heater trace is disposed in a first layer of the IC package support structure, and the second heater trace is disposed in a second layer, different from the first layer, of the IC package support structure.

10. The IC package support structure of claim 9, wherein a footprint of the first heater trace does not overlap with a footprint of the second heater trace.

11. The IC package support structure of claim 9, wherein a footprint of the first heater trace overlaps with a footprint of the second heater trace.

12. The IC package support structure of claim 11, wherein a first portion of the first heater trace is disposed in an area in which the footprint of the first heater trace overlaps with the footprint of the second heater trace, a second portion of the first heater trace is disposed in an area in which the footprint of the first heater trace does not overlap the footprint of the second heater trace, and a width of the first portion of the first heater trace is greater than a width of the second portion of the first heater trace.

13. The IC package support structure of claim 9, further comprising:
a metal plane disposed in a third layer of the IC package support structure, wherein the third layer is different from the first and second layers and the IC package support structure does not include conductive contacts to the metal plane.

14. The IC package support structure of claim 1, further comprising:
conductive contacts; and
a ball grid array (BGA) package coupled to the conductive contacts via solder.

15. The IC package support structure of claim 1, further comprising:
a first region of vias proximate to the first heater trace; and
a second region of vias proximate to the second heater trace.

16. The IC package support structure of claim 15, wherein a density of the vias in the first region is greater than a density of the vias in the second region.

17. The IC package support structure of claim 16, further comprising:
a heater control device in conductive contact with the first heater trace and the second heater trace;
wherein the heater control device is to deliver more power to the first heater trace than the second heater trace.

18. A computing device, comprising:
an integrated circuit (IC) package support structure, including:
a first heater trace,
a second heater trace, wherein the second heater trace is not conductively coupled to the first heater trace in the IC package support structure, and
a plurality of conductive contacts disposed at a surface of the IC package support structure; and
an IC package conductively coupled to the plurality of conductive contacts.

19. The computing device of claim 18, wherein the IC package is a ball grid array (BGA) package, and the IC package is conductively coupled to the plurality of conductive contacts via solder.

20. The computing device of claim 18, wherein the IC package support structure is an interposer, and the computing device further comprises:
a motherboard conductively coupled to the interposer such that the interposer is disposed between the IC package and the motherboard.

21. The computing device of claim 18, wherein the IC package support structure is a motherboard.

22. The computing device of claim 18, wherein the first heater trace is disposed in the IC package support structure to, when a first power is dissipated in the first heater trace, generate heat to melt solder disposed on the plurality of conductive contacts.

23. A method of manufacturing an integrated circuit (IC) package support structure, comprising:
providing first and second insulating layers;
providing a first heater trace between the first and second insulating layers;
providing a second heater trace between the first and second insulating layers, wherein the second heater trace is not conductively coupled to the first heater trace; and
providing conductive contacts at a surface of the second insulating layer.

24. The method of claim 23, further comprising:
providing a third insulating layer, wherein the third insulating layer is disposed between the first heater trace and the second heater trace.

25. The method of claim 23, further comprising:
providing a metal plane between the first and second insulating layers; and
providing power and ground contacts;
wherein the metal plane is not conductively coupled to the power or ground contacts.
